(19) United States
(12) Patent Application Publication
(10) Pub. No.: US 2010/0116209 A1
(43) Pub. Date: May 13, 2010

(54) FILM DEPOSITION APPARATUS

(75) Inventor: HITOSHI KATO, Oshu-Shi (JP)

Correspondence Address: IPUSA, P.L.L.C, 1054 31ST STREET, N.W., Suite 400, Washington, DC, 20007, US

(73) Assignee: TOKYO ELECTRON LIMITED

(21) Appl. No.: 12/615,297

(22) Filed: Nov. 10, 2009

(30) Foreign Application Priority Data
Nov. 10, 2008 (JP) 2008-288124

(51) Int. Cl. C23C 16/00

(52) U.S. Cl. 118/730; 118/715

(57) ABSTRACT

A film deposition apparatus including a rotational member is rotated by a rotation mechanism around a vertical axis inside a chamber, a pedestal in the chamber and including substrate receiving areas formed along a circle having the vertical axis as a center, and first and second reaction gas supplying parts provided separately along a circumferential direction of the circle and supplying first and second reaction gases to the pedestal, a separating area in the rotational member and between first and second process areas to which first and second reaction gases are supplied, an evacuation port to evacuate an atmosphere inside the chamber, a separation gas supplying part in the separating area for supplying a separation gas, and an opposing surface part in the separating area on both sides of the separation gas supplying part and at a position forming a thin space between the opposing surface part and the pedestal.

### CROSS-REFERENCE TO RELATED APPLICATIONS

This application is based upon and claims the benefit of priority of the prior Japanese Patent Application No. 2008-288124 filed on Nov. 10, 2008, the entire contents of which are incorporated herein by reference.

### BACKGROUND OF THE INVENTION

1. Field of the Invention

The present invention generally relates to a film deposition apparatus for depositing a film on a substrate by carrying out cycles of supplying in turn at least two source gases to the substrate in order to form one or more layers of a reaction product.

2. Description of the Related Art

As a film deposition technique in a semiconductor fabrication process, there is a technique in which a first reaction gas is adsorbed on a surface of a semiconductor wafer (referred to as a wafer hereinafter) under vacuum and then a second reaction gas is adsorbed on the surface of the wafer in order to form one or more atomic or molecular layers through reaction of the first and the second reaction gases on the surface of the wafer; and such an alternating adsorption of the gases is repeated plural times, thereby depositing a film on the wafer. This technique is referred to as, for example, Atomic Layer Deposition (ALD) or Molecular Layer Deposition (MLD). This technique is advantageous in that the film thickness can be controlled at higher accuracy by the number of times of alternately supplying the gases, and in that the deposited film can have excellent uniformity over the wafer. Therefore, this deposition method is thought to be promising as a film deposition technique that can address further miniaturization of semiconductor devices.

Such a film deposition method may be preferably used, for example, for depositing a dielectric material to be used as a gate insulator. When silicon dioxide (SiO₂) is deposited as the gate insulator, a bis (tertiary-butylamino) silane (BTBAS) gas or the like is used as a first reaction gas (source gas) and ozone gas or the like is used as a second gas (oxidation gas).

In order to carry out such a deposition method, use of a single-wafer deposition apparatus having a gas shower head provided at a center top portion of a vacuum chamber is being considered. With such a deposition method using the deposition apparatus, reaction gases are supplied from a center upper side of a substrate, and unreacted gases and by-products are evacuated from a bottom portion of a process chamber. In this case, replacing reaction gases by using purge gas takes a long time and the number of cycles may reach several hundred. This results in a problem of an extremely long process time. Therefore, a deposition method and apparatus that enable high throughput is desired.

Under these circumstances, there is known an apparatus that performs a deposition process on plural wafers placed on a rotation table in a circumferential direction inside a vacuum chamber.

United States Patent Publication No. 7,153,542 (FIGS. 6A, 6B) (hereinafter referred to as “Patent Document 1”) describes the following structure. A flattened cylindrical-shaped vacuum chamber is divided into a left side area and a right side area. Evacuation openings are formed along outlines of semicircles at the left side area and the right side area for upward evacuation. An eject opening of separation gas is formed between the outline of the left side semicircle and the outline of the right side semicircle, namely a diameter area of the vacuum chamber. A supply area of a different material gas is formed in each of a right side semicircle area and a left side semicircle area. By rotating a rotation table in the vacuum chamber, a work piece passes through the right side semicircle area, the separation area D, and the left side semicircle area and the material gases are evacuated from the evacuation opening. Further, the ceiling of the separation area D supplying separation gas is lower than the supply area of material gas.

However, in the apparatus described in Patent Document 1, the upward evacuation openings are formed between the eject opening of the separation gas and the supply area of the reaction gas. In addition, the reaction gas is evacuated with the separation gas from the evacuation openings. Accordingly, the reaction gas ejected toward the work piece is drawn in from the evacuation openings as an upward flow so that particles in the chamber may be blown upward by the upward flow of the gases and fall on the wafers, leading to contamination of the wafers.

Japanese Patent Application Laid-Open Publication No. 2001-254181 (FIGS. 1, 2) (hereinafter referred to as “Patent Document 2”) describes a process chamber having a wafer support member (rotation table) that holds plural wafers and that is horizontally rotatable, first and second gas ejection nozzles that are located at equal angular intervals along the rotation direction of the wafer support member and oppose the wafer support member, and purge nozzles that are located between the first and the second gas ejection nozzles. The gas ejection nozzles extend in a radial direction of the wafer support member. A top surface of the wafers is higher than a top surface of the wafer support member, and the distance between the ejection nozzles and the wafers on the wafer support member is about 0.1 mm or more. A vacuum evacuation apparatus is connected to a part between the outer edge of the wafer support member and the inner wall of the process chamber. According to a process chamber so configured, the purge gas nozzles discharge purge gases to create a gas curtain, thereby preventing the first reaction gas and the second reaction gas from being mixed.

However, in the technique described in Patent Document 2, the wafer support member is rotated. Accordingly, it is not possible to prevent the reaction gas at both sides of the purge gas nozzle from passing by only the air curtain action from the purge gas nozzle. Hence, it is not possible to avoid the reaction gas being diffused in the air curtain from an upstream side in the rotational direction. Furthermore, the first reaction gas ejected from the first reaction gas ejecting nozzle easily reaches the second reaction gas diffusion area via a center part of the wafer support member corresponding to the rotation table. Once the first and second reaction gases are mixed on the wafer, an MLD (or ALD) mode film deposition cannot be carried out because the reaction product is adhered to a surface of the wafer.

Japanese Patent Publication No. 3,144,664 (FIGS. 1, 2, claim 1) (hereinafter referred to as “Patent Document 3”) describes a process chamber that is divided into plural process areas along the circumferential direction by plural partitions. Below the partitions, a circular rotatable susceptor on which plural wafers are placed is provided leaving a slight gap in relation to the partitions. In the technique described in Patent Document 3, the process gas is diffused to a neighboring process chamber from a gap between the partition and the susceptor. Furthermore, an evacuation room is provided among plural process chambers. Hence, when the wafer passes through the evacuation room, a gas from the process chamber at an upstream side and a gas from the process chamber at a downstream side are mixed. Because of this, this structure cannot be applied to the ALD type film deposition method.

Japanese Patent Application Laid-Open Publication No. H4-287912 (hereinafter referred to as “Patent Document 4”) describes a structure where a circular-shaped gas supply plate is divided into eight parts in a circumferential direction. A supply opening of AsH₂ gas, a supply opening of H₂ gas, a supply opening of TMG gas, and a supply opening of H₂ gas are arranged at intervals of 90 degrees. In addition, evacuation openings are provided between neighboring gas openings. A susceptor configured to support a wafer and facing these gas supply openings is rotated. However, Patent Document 4 does not provide any realistic measures to prevent two source gases (AsH₃, TMG) from being mixed. Because of the lack of such measures, the two source gases may be mixed around the center of the susceptor and through the H₂ gas supplying plates. Moreover, because the evacuation ports are located between the adjacent two gas supplying plates to evacuate the gases upward, particles are blown upward from the susceptor surface, which leads to wafer contamination.

United States Patent Publication No. 6,634,314 (hereinafter referred to as “Patent Document 5”) describes a process chamber having a circular plate that is divided into four quarters by partition walls and has four susceptors respectively provided in the four quarters, four injector pipes connected into a cross shape, and two evacuation ports located near the corresponding susceptors. In this process chamber, four wafers are mounted in the corresponding four susceptors, and the four injector pipes rotate around the center of the cross shape above the circular plate while ejecting a source gas, a purge gas, a reaction gas, and another purge gas, respectively. However, in the technique described in Patent Document 5, after the source gas or the reaction gas is supplied to each of the four quarters, an atmosphere of each of the four quarters is displaced by purge gas by using the purge nozzle, which takes a long time. Furthermore, the source gas or the reaction gas is diffused from one of the four quarters to the neighboring ones of the four quarters beyond vertical walls. Hence, both gases may be reacted in the four quarters.

Furthermore, Japanese Patent Application Laid-Open Publication No. 2007-247066 (paragraphs 0023 through 0025, 0058, FIGS. 12 and 13) (hereinafter referred to as “Patent Document 6”), (United States Patent Publication No. 2007-218701 (hereinafter referred to as “Patent Document 7”), and United States Patent Publication No. 2007-218702 (hereinafter referred to as “Patent Document 8”)) describe a film deposition apparatus preferably used for an Atomic Layer CVD method that causes plural gases to be alternately adsorbed on a target (a wafer). In the apparatus, a susceptor that holds the wafer is rotated, while source gases and purge gases are supplied to the susceptor from above. Paragraphs 0023, 0024, and 0025 of Patent Document 6 describe partition walls that extend in a radial direction from the center of a chamber, and gas ejection holes that are formed in the bottom of the partition walls in order to supply the source gases or the purge gas to the susceptor, so that an inert gas as the purge gas ejected from the gas ejection holes produces a gas curtain. Regarding evacuation of the gases, paragraph 0058 of Patent document 6 describes that the source gases are evacuated through an evacuation channel 30a, and the purge gases are evacuated through an evacuation channel 30b. With such a configuration, the source gases can flow into a purge gas compartment from source gas compartments located on both sides of the purge gas compartment and the gases can be mixed with each other in the purge gas compartment. As a result, a reaction product is generated in the purge gas compartment, which may cause particles to fall onto the wafer and result in wafer contamination.

### SUMMARY OF THE INVENTION

The present invention may provide a film deposition apparatus that substantially eliminates one or more of the problems caused by the limitations and disadvantages of the related art.

Features and advantages of the present invention will be set forth in the description which follows, and in part will become apparent from the description and the accompanying drawings, or may be learned by practice of the invention according to the teachings provided, in the description. Objects as well as other features and advantages of the present invention will be realized and attained by a film deposition apparatus particularly pointed out in the specification in such full, clear, concise, and exact terms as to enable a person having ordinary skill in the art to practice the invention.

To achieve these and other advantages and in accordance with the purpose of the invention, as embodied and broadly described herein, an embodiment of the present invention provides a film deposition apparatus for depositing a film on a substrate by carrying out a cycle of alternately supplying at least two kinds of reaction gases that react with each other to the substrate to produce a layer of a reaction product in a chamber, the film deposition apparatus including: a rotational member that is rotatable around a vertical axis inside the chamber; a rotation mechanism configured to rotate the rotational member; a pedestal provided in the chamber, the pedestal including a plurality of substrate receiving areas formed along a circle having the vertical axis as a center; a first reaction gas supplying part provided in the rotational member and configured to supply a first reaction gas to the pedestal; a second reaction gas supplying part provided in the rotational member and configured to supply a second reaction gas to the pedestal, the second reaction gas supplying part being separated from the first reaction gas supplying part along a circumferential direction of the circle; a separating area provided in the rotational member along the circumferential direction of the circle, the separating area being arranged between a first process area to which the first reaction gas is supplied and a second process area to which the second reaction gas is supplied for separating an atmosphere of the first process area and an atmosphere of the second process area; an evacuation port configured to evacuate an atmosphere inside the chamber; a separation gas supplying part provided in the separating area and configured to supply a separation gas; and an opposing surface part provided in the separating area on both sides of the separation gas supplying part in the circumferential direction of the circle and arranged at a position forming a thin space between the opposing surface part and the pedestal for allowing the separation gas to flow from the separating area to the first and second process areas.

Other objects and further features of the present invention will be apparent from the following detailed description when read in conjunction with the accompanying drawings.

### BRIEF DESCRIPTION OF THE DRAWINGS

FIG. 1 is a vertical cross-sectional view of a film deposition apparatus according to an embodiment of the present invention taken along I-I line in FIG. 2;

FIG. 2 is a perspective view of the film deposition apparatus illustrated in FIG. 1;

FIG. 3 is a plan view of the film deposition apparatus illustrated in FIG. 1;

FIGS. 4A and 4B are vertical developed cross-sectional views showing a separation area and a process area according to an embodiment of the present invention;

FIG. 5 is a perspective view illustrating a schematic configuration of the inside of a rotational cylinder constituting a rotation mechanism of a film deposition apparatus according to an embodiment of the present invention;

FIG. 6 is a schematic diagram illustrating an outer view of a film deposition apparatus according to an embodiment of the present invention;

FIGS. 7A-7C are schematic diagrams for describing effects of a film deposition apparatus according to an embodiment of the present invention;

FIG. 8 is a schematic diagram illustrating a modified example of a film deposition apparatus according to an embodiment of the present invention;

FIG. 9 is a vertical cross-sectional view of a film deposition apparatus according to another embodiment of the present invention;

FIG. 10 is a perspective view of the film deposition apparatus illustrated in FIG. 9;

FIGS. 11A-11B are schematic diagrams for describing the size of a sector part in a separation area according to an embodiment of the present invention;

FIG. 12 is a vertical cross-sectional view of another example of a sector part according to an embodiment of the present invention;

FIGS. 13A-13C are vertical cross-sectional views of other examples of a sector part according to an embodiment of the present invention;

FIGS. 14A-14C are bottom views of examples of ejecting holes of a separation gas supplying part according to an embodiment of the present invention;

FIGS. 15A-15D are bottom views of examples of a separation area according to an embodiment of the present invention;

FIG. 16 is a horizontal plan view of a film deposition apparatus according to yet another embodiment of the present invention;

FIG. 17 is a horizontal plan view of a film deposition apparatus according to yet another embodiment of the present invention;

FIG. 18 is a horizontal plan view of a film deposition apparatus according to yet another embodiment of the present invention; and

FIG. 19 is a plan view showing an example of a substrate process system using the film deposition apparatus of the embodiments of the present invention.

### DESCRIPTION OF THE PREFERRED EMBODIMENTS

In the following, embodiments of the present invention will be described with reference to the accompanying drawings.

### First Embodiment

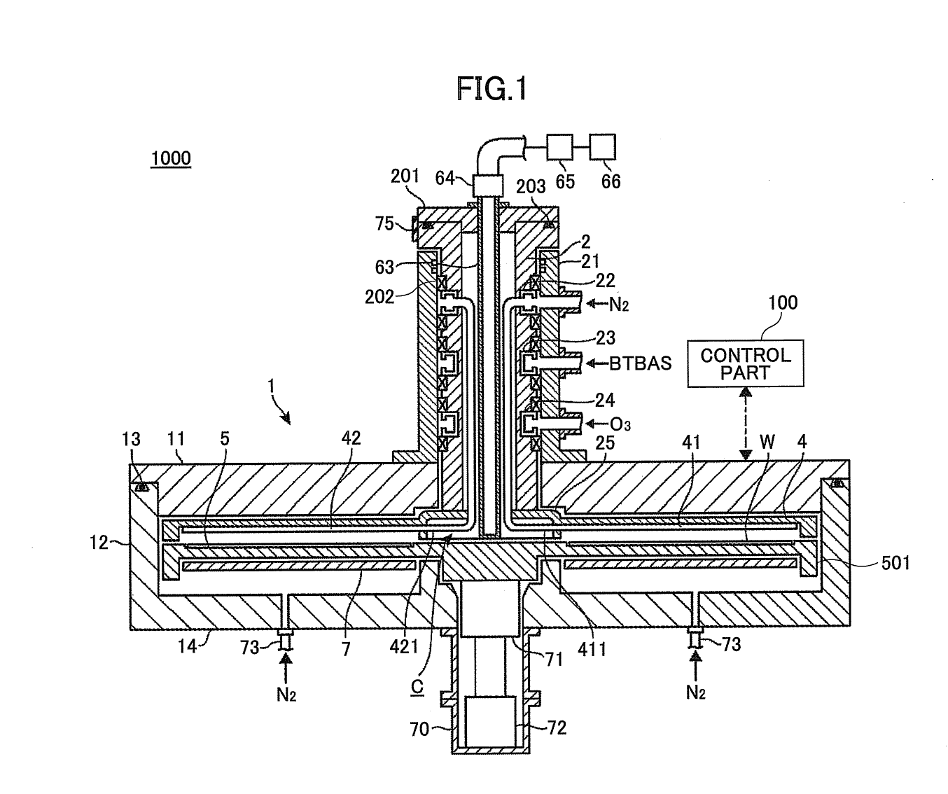

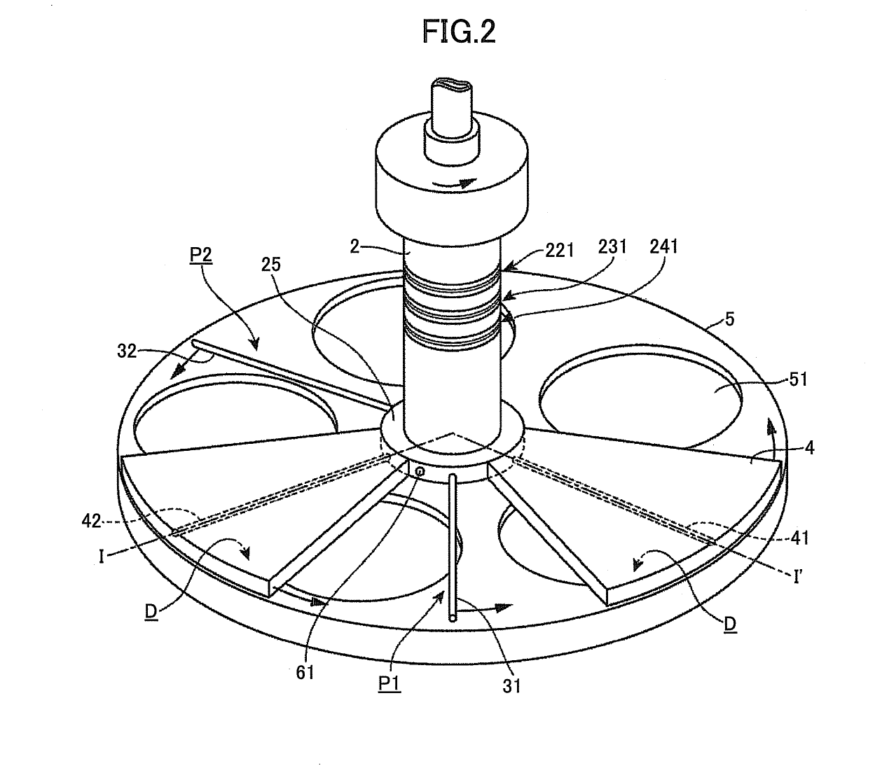

Referring to FIG. 1, which is a cut-away diagram taken along I-I′ line in FIG. 2, a film deposition apparatus 1000 according to an embodiment of the present invention has a vacuum chamber 1 having a flattened cylinder shape, and a susceptor (pedestal) 5 that is located inside the vacuum chamber 1. The vacuum chamber 1 is made so that a ceiling plate 11 can be separated from a chamber body 12. The ceiling plate 11 is pressed onto the chamber body 12 by internal decompression via a ceiling member such as an O ring 13, so that the vacuum chamber 1 is hermetically sealed. On the other hand, the ceiling plate 11 can be raised by a driving mechanism (not shown) when the ceiling plate 11 has to be separated from the chamber body 12.

In this embodiment, the susceptor 5 is substantially a flat member having a top view shape of a circle. A center part located at a bottom surface of the susceptor 5 is fixed to a rotational shaft 71 extending in a vertical direction. In a case of transferring a wafer W into the vacuum chamber 1 via the below-described transfer opening 15, the susceptor 5 is rotated so that the wafer is placed (received) onto a predetermined receiving area. In FIG. 1, reference numeral 72 represents a driving part of the rotational shaft 71 and reference numeral 70 represents a cylindrical case body. A hermetically sealed state is maintained by isolating the inner environment (atmosphere) of the case body 70 from an outer environment (atmosphere).

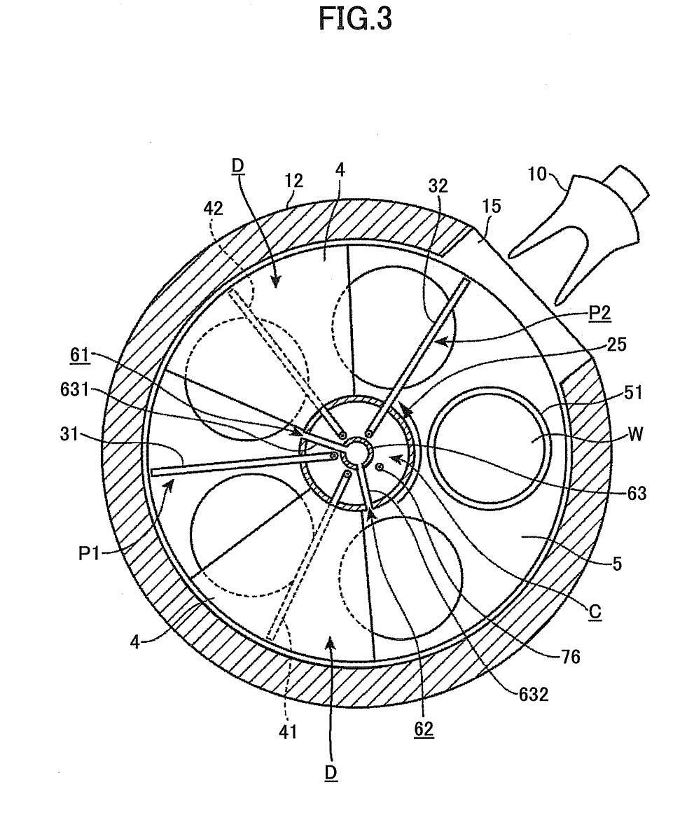

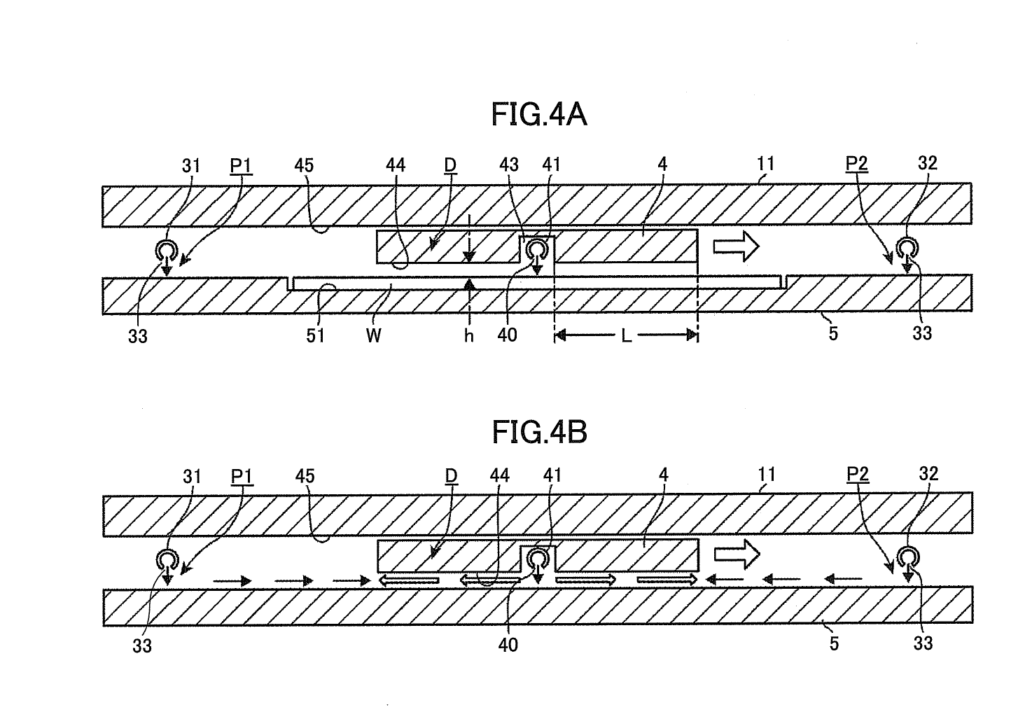

As shown in FIGS. 2 and 3, plural (five in the illustrated example) circular concave parts 51, each of which receives a wafer W, are formed in a top surface of the susceptor 5 along a circumferential direction (circumferential direction of a circle having the rotational axis of the below-described core part 25 as its center), although only one wafer W is shown in FIG. 3. FIG. 4 is a developed view of the susceptor 5 taken along concentric circles and horizontally developed with respect to the circumferential direction. As shown in FIG. 4A, the concave part 51 has a diameter slightly larger, for example, by 4 mm, than the diameter of the wafer W and a depth equal to the thickness of the wafer W. Therefore, when the wafer W is placed in the concave part 51, the exposed surface of the wafer W is at the same elevation as the surface of an area of the susceptor 5, the area excluding the concave parts 51. If there is a relatively large step between the area and the wafer W, gas flow turbulence is caused by the step, which may affect thickness uniformity across the wafer W. This is why the two surfaces are at the same elevation. While “the same elevation” may mean here that a height difference is less than or equal to about 5 mm, the difference is made to be as close to zero as possible to the extent allowed by machining accuracy. In the bottom surface of the concave part 51, there are formed three through holes (not shown) through which below-described three corresponding elevation pins (not shown) are raised/lowered. The elevation pins support a back surface of the wafer W and raise/lower the wafer W.

The concave parts 51 are configured to position the wafers W. The concave parts 51 correspond to a substrate providing area (wafer providing area). The substrate providing area is not limited to the concave part 51. The substrate providing area may have a structure where, for example, plural guide members configured to guide a circumferential edge of the wafer are arranged in the circumferential direction of the wafer W at the surface of the susceptor 5. Alternatively, the substrate providing area may be an area where the wafer W is provided by attraction in a case where a chuck mechanism such as an electrostatic chuck is provided at the susceptor 5 so that the wafer W is held by an attraction force.

Referring again to FIGS. 2 and 3, the chamber 1 includes a first reaction gas nozzle 31, a second reaction gas nozzle 32, and two separation gas nozzles 41, 42, all of which extend in radial directions and are arranged at predetermined angular intervals in a circumferential direction of the chamber 1. The first reaction gas nozzle 31, the second reaction gas nozzle 32, and the separation gas nozzles 41, 42 are attached to a cylindrically shaped core part 25 provided immediately above the center part of the susceptor 5. The base end parts of the first reaction gas nozzle 31, the second reaction gas nozzle 32, and the separation gas nozzles 41, 42 penetrate through the sidewall of the core part 25. As described below, the core part 25 constitutes a part of a rotational member. By rotating the core part 25 around its vertical axis in the vacuum chamber 1, the gas nozzles 31, 32, 41, 42 can be rotated above the susceptor 5. In this embodiment, the second reaction gas nozzle 32, the separation gas nozzle 41, the first reaction gas nozzle 31, and the other separation gas nozzle 42 are arranged in this order in a clockwise direction.

The reaction gas nozzles 31, 32 have plural ejection holes 33 to eject the corresponding source gases downward. The plural ejection holes 33 are arranged in longitudinal directions of the reaction gas nozzles 31, 32 at predetermined intervals. In addition, the separation gas nozzles 41, 42 have plural ejection holes 40 to eject the separation gases downward from the plural ejection holes 40. The plural ejection holes 40 are arranged at predetermined intervals in longitudinal directions of the separation gas nozzles 41, 42. The reaction gas nozzles 31, 32 are a first reaction gas supplying part and a second reaction gas supplying part, respectively, in this embodiment. In addition, an area below the reaction gas nozzle 31 is a first process area P1 in which the BTBAS gas is adsorbed on the wafer W, and an area below the reaction gas nozzle 32 is a second process area P2 in which the O₃ gas is adsorbed on the wafer W. Further, the separation gas nozzles 41, 42 correspond to separation gas supplying parts.

The separation gas nozzles 41, 42 are provided in separation areas D that are configured to separate the first process area P1 and the second process area P2. In each of the separation areas D, there is provided a sector part 4 on the ceiling plate 11, as shown in FIGS. 2 through 4. The sector part 4 has a top view shape of a sector whose opposing surface part forms a thin space between the susceptor 5 and whose arced periphery lies near and along the inner circumferential wall of the chamber 1. The sector part 4 is fixed to the sidewall of the core part 25, so that the sector part 4 is configured to rotate above the susceptor 5 together with the gas nozzles 31, 32, 41, and 42.

The separation gas nozzle 41 (42) is located in the groove part 43. A circumferential distance between the center axis of the separation gas nozzle 41 (42) and one side of the sector part 4 is substantially equal to the circumferential distance between the center axis of the separation gas nozzle 41 (42) and the other side of the sector part 4.

Although the groove part 43 in this embodiment is formed so that the sector part 4 is divided into substantially two equal halves, the groove part 43 may be formed so that a downstream half of the sector part 4 is wider than an upstream half of the sector part 4 with respect to the rotation direction.

Accordingly, there are flat low ceiling surfaces (first ceiling surfaces) 44, as a lower surface of the sector part 4 (opposing surface part illustrated in FIG. 4), on both sides in the circumferential direction of the separation gas nozzle 41 (42), and high ceiling surfaces (second ceiling surfaces) 45 higher than the first ceiling surfaces 44 on both sides in the circumferential direction of the separation gas nozzle 41 (42). The sector part 4 provides a separation space, which is a thin space with height “h”, between the opposing surface part of the sector part 4 and the susceptor 5 in order to prevent the first and the second source gases from entering the thin space and from being mixed.

Referring to FIGS. 4A and 4B, the O₃ gas is prevented from entering the thin space between the sector part 4 and the susceptor 5 from the upstream side in the rotational direction of the susceptor 5. The BTBAS gas is prevented from entering the thin space between the convex part 4 and the susceptor 5 from the downstream side in the rotational direction of the susceptor 5. “The gases being prevented from entering” means that the N₂ (nitrogen) gas as the separation gas ejected from the separation gas nozzle 41 diffuses between the first ceiling surfaces 44 and the upper surface of the susceptor 5 and flows out to spaces below the second ceiling surfaces 45 adjacent to the corresponding first ceiling surfaces 44 in the illustrated example, so that the source gases cannot enter the thin separation space from the adjacent spaces. “The gases cannot enter the separation space” means not only that the gases are completely prevented from entering the thin space below the convex part 4 from the adjacent spaces, but also that small amounts of entering O₃ gas and BTBAS gas may be mixed in the thin space below the sector part 4. As long as such effect is demonstrated, it is possible to perform the separation action of the separation area D, namely separating the atmosphere of the first process area P1 and the atmosphere of the second process area P2. The thinness of the thin space is set to enable the pressure difference between the thin space (thin space below the sector part 4) and the adjacent spaces (in this embodiment, spaces below the second ceiling surfaces 45) to establish the effect of “The gases cannot enter the separation space”. Thus, the specific measurements of the thin space differ depending on, for example, the area of the sector part 4. In addition, the gas adsorbed on the wafer W can pass through the separation area D. Therefore, the gases in “the gases being impeded from entering” mean the gases in a gaseous phase.

In this embodiment, in the separation gas nozzle 41 (42), ejection holes having an inner diameter of about 0.5 mm are arranged at intervals of about 10 mm. In addition, in the reaction gas nozzle 31 (32), the ejection holes 33 having an inner diameter of about 0.5 mm are arranged at intervals of about 10 mm in this embodiment.

When the wafer W having a diameter of about 300 mm is to be processed in the chamber 1, the sector part 4 has a circumferential length of, for example, about 146 mm along an inner arc (engaging area with respect to the core part 25) that is at a distance 140 mm from the rotational center of the susceptor 5, and a circumferential length of, for example, about 502 mm along an outer arc corresponding to the outermost part of the concave parts 51 of the susceptor 5 in this embodiment. In addition, as illustrated in FIG. 4A, a circumferential length from one sidewall of the sector part 4 through the nearest sidewall of the groove part 43 along the outer arc is about 246 mm.

In addition, the height h (see FIG. 4A) of the lower surface of the sector part 4, or the first ceiling surface 44, measured from the top surface of the susceptor 5 is, for example, approximately 0.5 mm through approximately 10 mm, and preferably approximately 4 mm. In this case, the rotational speed of the sector part 4 or the separation gas nozzles 31, 32, 41, 42 is, for example, 1 through 500 revolutions per minute (rpm). In order to ascertain the separation function performed by the separation area D, the size of the sector part 4 and the height h of the lower surface of the sector part (first ceiling surface 44) from the susceptor 5 may be determined depending on the rotational speed of the sector part 4 through experiment. The separation gas is N₂ in this embodiment but may be an inert gas such as Ar in other embodiments, as long as the separation gas does not affect the deposition process (in this embodiment, deposition of silicon dioxide).

Further, the space between the outer edge part of the sector part 4 and the inner circumferential surface of the vacuum chamber 1 and the space between the upper surface of the sector part 4 and the ceiling surface (ceiling plate 11) of the vacuum chamber 1 are also formed having a height “h” or less so as to serve as a thin space for preventing reaction gases from mixing. Further, the groove part 43 may be formed in a manner penetrating through the upper surface of the sector part 4, and ejection holes 40 may be provided in the upper parts of the separation gas nozzles 41, 42, so that separation gas can also be ejected upward toward the ceiling surface of the vacuum chamber 1.

Returning to the description of the configuration of the susceptor 5, the outer edge part of the susceptor 5 has a bent part 501 that forms an L-shape so that the bent part 501 faces the internal circumferential surface of the vacuum chamber 1 (chamber body 12). Because the susceptor 5 is to be rotated when wafers W are transferred into the vacuum chamber 1, there are slight gaps between the external circumferential surface of the susceptor 5 and the internal circumferential surface of the vacuum chamber 1. Hence, the bent part 501, as well as the sector part 4, prevents the reaction gases from entering from both sides and from being mixed. The gaps between the external circumferential surface of the bent part 501 and the internal circumferential surface of the chamber body 12 may be the same as the height h of the first ceiling surface 44 from the susceptor 5.

For example, as shown in FIG. 2 and FIG. 3, two evacuation ports 61 and 62 are provided at upstream sides of the separation gas nozzles 31, 32 in the rotational direction and immediately before (i.e. downstream of) the engaging area between the sector part 4 and the core part 25. The evacuation ports 61 and 62 are connected to corresponding evacuation pipes 63. The evacuation ports 61, 62 are for evacuating reaction gases and separation gases from the process areas P1, P2. The evacuation ports 61 and 62 are provided one at each side of (in between) the separation areas D in the rotational direction as seen from the top so that the separation action of the separation areas D securely functions and evacuation of each of the reaction gases (BTBAS gas and O₃ gas) is exclusively performed. In this embodiment, the evacuation port 61 is provided between the first reaction gas nozzle 31 and the separation area D neighboring an upstream side in the rotational direction relative to the reaction gas nozzle 31. The evacuation port 62 is provided between the second reaction gas nozzle 32 and the separation area D neighboring the upstream side in the rotation direction relative to the reaction gas nozzle 32.

Although the two evacuation ports 61, 62 are made in the chamber body 12 in this embodiment, three evacuation ports may be provided in other embodiments. For example, an additional evacuation port may be made in an area between the separation area D including the separation gas nozzle 42 and the second reaction gas nozzle 32 neighboring the upstream side in the rotational direction relative to the separation area D. In addition, four or more evacuation ports may be provided. In this case, the gases flow along the upper surface of the susceptor 5 into the evacuation ports 61, 62 located higher than the susceptor 5. Therefore, it is advantageous in that particles in the chamber 1 are not blown upward by the gases, compared to when the gases are evacuated from the ceiling surface facing the susceptor 5.

As shown in FIG. 1, a heater unit 7 as a heating part (e.g., carbon wire heater) is provided in a space between the bottom part 14 of the chamber body 12 and the susceptor 5, so that the wafers W placed on the susceptor 5 are heated through the susceptor 5 at a temperature determined by a process recipe. In addition, plural purge gas supplying pipes 73 are provided in a position downstream of the heater unit 7 at the bottom part 14 of the vacuum chamber 1 in the circumferential direction. The purge gas supplying pipes 73 are configured to purge a space where the heater unit 7 is housed. With this structure, BTBAS gas (O₃ gas) is prevented from flowing from the first processing area P1 (the second processing area P2) to the second processing area P2 (the first processing area P1) via a lower part of the susceptor 5. Hence, the purge gas functions as separation gas.

In addition, a transfer opening 15 is formed in a sidewall of the vacuum chamber 1 as shown in FIG. 3. Through the transfer opening 15, the wafer W is transferred between an outside transfer arm 10 and the susceptor 5. The transfer opening 15 is provided with a gate valve (not shown) by which the transfer opening 15 is opened or closed. The susceptor 5 is rotated by the driving part 72 and the concave part 51 is stopped at a position in alignment with the transfer opening 15, so that the wafer W can be received using the transfer arm 10. In order to lower/raise the wafer W into/from the concave part 51, there are provided elevation pins (not shown) that are raised or lowered through the concave part 51 by an elevation mechanism (not shown).

The above-described embodiment of the film deposition apparatus 1000 includes a mechanism for allowing the reaction gas nozzles 31, 32, the separation gas nozzles 41, 42, and the sector part 4 to rotate around the core part 25 while supplying reaction gas onto the surface of the wafer W placed on the susceptor 5. The mechanism is described in detail below.

In the embodiment illustrated in FIG. 1, a lower end part of a rotational cylinder 2 is connected to an upper center surface portion of the core part 25. By rotating the rotational cylinder 2 inside a sleeve 21 fixed to the ceiling plate 11 of the vacuum chamber 1, the core part 25 is rotated inside the vacuum chamber 1. In this embodiment, the core part 25 and the rotational cylinder 2 correspond to a rotational member. There is a space provided in a lower surface side of the core part 25. The reaction gas nozzles 31, 32 and the separation gas nozzles 41, 42 penetrating through the sidewall of the core part 25 are connected to corresponding first reaction gas supplying pipe 311 for supplying BTBAS gas (first reaction gas), second reaction gas supplying pipe 321 for supplying O₃ gas (second reaction gas), and separation gas supplying pipes 411, 421 for supplying N₂ gas (separation gas). For the sake of convenience, only the separation gas supplying pipes 411, 421 are illustrated in FIG. 1 and the first and second reaction gas supplying pipes 311, 321 are omitted.

The gas supplying pipes 311, 321, 411, 421 are provided in the vicinity of the rotation center of the core part 25 (more specifically, at the periphery of the below-described evacuation pipes 63) and bent in an L-shape in such a manner that the gas supplying pipes 311, 321, 411, 421 extend upward, penetrate through the ceiling surface of the core part 25, and further extend vertically inside the rotational cylinder 2.

As illustrated in FIGS. 1, 2, and 5, the rotational cylinder 2 is formed of two levels of cylinders formed on top of each other having different outer diameters. By engaging a bottom surface of the cylinder having the larger outer diameter with an upper edge surface of the sleeve 21, the rotational cylinder 2 is rotatably mounted in the circumferential direction of the rotational cylinder 2 inside the sleeve 21. Further, a lower edge side of the rotational cylinder 2 penetrates through the ceiling plate 21 and is connected to the upper surface of the core part 25. At the outer circumferential surface side of the rotational cylinder 2, gas diffusion paths are arranged at predetermined intervals in a vertical direction. The gas diffusion paths are annular flow paths formed across the entire circumference of the outer circumferential surface of the rotational cylinder 2. In this embodiment, a separation gas diffusion path 22 is provided at an upper level position for diffusing separation gas (N₂ gas), a first reaction gas diffusion path 23 is provided at a middle level position for diffusing the first reaction gas (BTBAS gas), and a second reaction gas diffusion path 24 is provided at a lower level position for diffusing the second reaction gas (O₃ gas). In FIG. 1, reference numeral 201 indicates a lid part of the rotational cylinder 2, and reference numeral 203 indicates an O-ring for tightly fastening the lid part 201 and the rotational cylinder 2 together.

The gas diffusion paths 22-24 include slits 221, 231, 241 that encompass the entire circumference of the rotational cylinder 2 and have openings facing outward from the outer surface of the rotational cylinder 2. The sleeve 21 surrounding the rotational cylinder 2 includes gas supply ports 222, 232, 242 that are positioned at the same height as the corresponding slits 221, 231, 241. The gases supplied from gas supply sources (not illustrated) to the gas supply ports 222, 232, 242 are supplied into the gas diffusion paths 22, 23, 24 via corresponding slits 221, 231, 241 facing the gas supply ports 222, 232, 242.

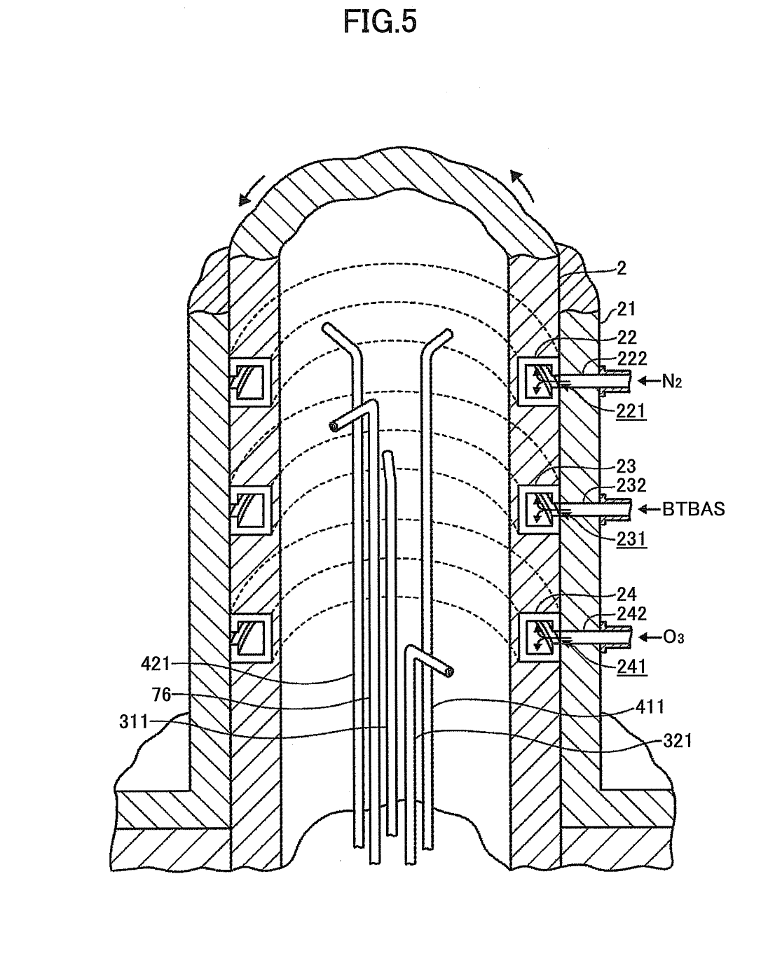

The rotational cylinder 2, which is inserted in the sleeve 21, is formed having an outer circumference within a range enabling rotation of the rotational cylinder 2. Within such range, the outer circumference of the rotational cylinder 2 is formed with a size as close as possible to the size of the inner circumference of the sleeve 21. Besides at the areas corresponding to the gas supply ports 222, 232, 242, the slits 221, 231, 241 are sealed by the inner circumferential surface of the sleeve 21. As a result, the gas introduced into each of the gas diffusion paths 22-24 diffuses only inside corresponding gas diffusion paths 22-24, so that the gas does not leak into, for example, other neighboring gas diffusion paths 22-24, the vacuum chamber 1, or outside of the film deposition apparatus 1000. In FIG. 1, reference numeral 202 represents magnetic seals that prevent gas from leaking from a space between the rotational cylinder 2 and the sleeve 21. These magnetic seals 202 are provided above and below each of the gas diffusion paths 22, 23, 24, so that the gas diffusion paths 22, 23, 24 can strictly seal the gas therein. For the sake of convenience, the magnetic seals 202 are omitted from FIG. 5.

With reference to FIG. 5, gas diffusion paths 22, 23, and 24 are connected to corresponding gas supply pipes 411-421, 311, and 321 at the inner circumference side of the rotational cylinder 2. Accordingly, the reaction gases and separation gas supplied from the gas supply ports 222, 232, and 242 diffuse inside the gas diffusion paths 22, 23, and 24 and flow into the gas supply nozzles 31, 32, 41, and 42 via the gas supply pipes 311, 321, 411, and 421, respectively. For the sake of convenience, the below-described evacuation pipe 63 is not illustrated in FIG. 5.

Further, as illustrated in FIG. 5, a purge gas supply pipe 76 is connected to the separation gas diffusion path 22. The purge gas supply pipe 76 is extended downward in the rotational cylinder 2 and has an opening facing the space inside the core part 25 as illustrated in FIG. 3. For example, as illustrated in FIG. 1, the core part 25 is supported by the rotational cylinder 2 so that the core part 25 is suspended in air (gap), for example, at a height h from the surface of the susceptor 5. The core part 25 can freely rotate because the core part 25 is not fixed to the susceptor 5. However, due to the gap between the susceptor 5 and the core part 25, BTBAS gas or O₃ gas may enter from one of the process areas P1 and P2 to the other one of the process areas P1 and P2 via the gap below the core part 25.

Accordingly, the core part 25 is formed having a hollow inside (inner space) and an opening facing the susceptor 5 at a bottom part of the core part 25. By supplying purge gas (N₂ gas) into the inner space and blowing out the purge gas to each of the process areas P1, P2 via the gap, the BTBAS gas or the O₃ gas can be prevented from traveling from one of the process areas P1 and P2 to the other one of the process areas P1 and P2 via the gap below the core part 25. In other words, the film deposition apparatus 1000 according to this embodiment separates the atmospheres of the process areas P1 and P2 by providing a center portion area C partitioned by a center portion of the susceptor 5 and the vacuum chamber 1 and forming an ejection port in a rotational direction of the core part 25 for enabling purge gas to be ejected to the surface of the susceptor 5. In this case, the purge gas acts as a separation gas for preventing BTBAS gas or O₃ gas from entering from one of the process areas P1 and P2 to the other one of the process areas P1 and P2 via the gap below the core part 25. In this embodiment, the ejection port corresponds to the gap between the susceptor 5 and the sidewall of the core part 25.

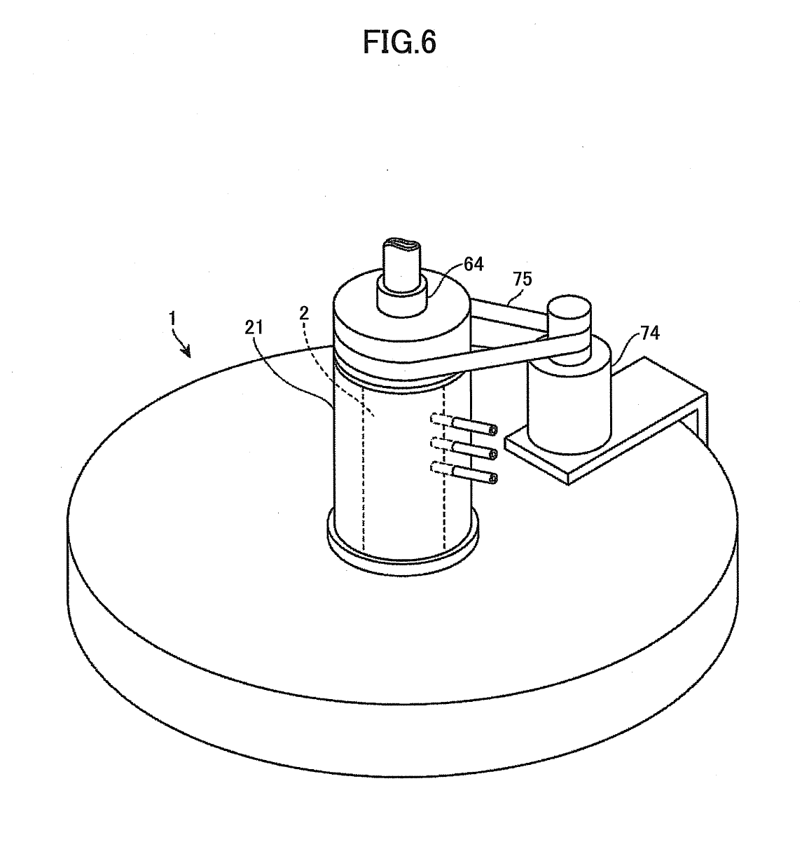

As illustrated in FIGS. 1 and 6, a driving belt 75 is wound around a side circumferential surface of a large outer diameter cylinder part at the top portion of the rotational cylinder 2. As illustrated in FIG. 6, a driving part 74 is arranged at an upper part of the vacuum chamber 1. A driving force generated from the driving part 74 is transmitted to the core part 25 via the driving belt 75. Thereby, the rotational cylinder 2 is rotated inside the sleeve 21. In this embodiment, the driving belt 75 and the driving part 74 form a rotation mechanism (first rotation mechanism) of the rotational cylinder 2 and the core part 25.

Next, an evacuation system according to an embodiment of the present invention is described. An evacuation pipe 63 is disposed at a rotation center of the rotational cylinder 2 as illustrated in FIG. 1. A lower end part of the evacuation pipe 63 penetrates through an upper surface of the core part 25 and extends into the inner space of the core part 25. Further, a lower end surface of the evacuation pipe 63 is hermetically sealed. Further, evacuation entrance conduits 631, 632, which are connected to evacuation ports 61, 62, are formed at the side surface of the evacuation pipe 63, as illustrated in FIG. 3. The evacuation entrance conduits 631, 632 are isolated from the inner atmosphere of the core part 25 filled with purge gas and allow the evacuation gas from each of the process areas P1, P2 to enter the evacuation pipe 63. It is to be noted that, although the evacuation pipe 63 is not illustrated in FIG. 5, the gas supply pipes 311, 321, 411, 421 and the purge gas supply pipe 76 are formed at the periphery of the evacuation pipe 63.

As illustrated in FIG. 1, an upper end part of the evacuation pipe 63 penetrates the lid part 201 of the rotational cylinder 2. The upper end part of the evacuation pipe 63 is connected to, for example, a vacuum pump (evacuation part) 66. In FIG. 1, reference numeral 65 represents a pressure adjusting part, and reference numeral 64 represents a rotary joint that enables the evacuation pipe 63 to be rotatably connected to a pipe on the downstream side.

In addition, the film deposition apparatus 1000 according to this embodiment is provided with a control part 100. The control part 100 is configured to control total operations of the film deposition apparatus 1000. A program for operating the apparatus is stored in a memory of the control part 100. A step group of performing the operations of the apparatus is provided in this program. This program is installed in the control part 100 from a storage medium such as a floppy disk, a memory card, an optical disk, a compact disk, and a hard disk.

Next, operations of the film deposition apparatus according to the above-described embodiment of the present invention are described. First, the gate valve (not shown) is opened so that the wafer W is delivered by the transfer arm 10 from the outside into the concave part 51 via the transfer opening 15. This delivery is performed by elevating the elevation pins from the bottom part side of the vacuum chamber 1 via the piercing holes of the bottom surface of the concave part 51 when the concave part 51 stops in a position facing the transfer opening 15 by rotating the susceptor 5. Such delivery of plural wafers W is performed by intermittently rotating the susceptor 5 so that one wafer W is provided in each of five concave parts 51. While the rotation cylinder 2 starts rotating counter-clockwise, the susceptor 5 is heated to a predetermined temperature (e.g., 300° C.) in advance by the heater unit 7, which in turn heats the wafers W on the susceptor 5. After the wafers W are heated and maintained at the predetermined temperature, which may be confirmed by a temperature sensor (not shown), the first reaction gas (BTBAS) is supplied to the first process area P1 through the first reaction gas nozzle 31, and the second reaction gas (O₃) is supplied to the second process area P2 through the second reaction gas nozzle 32. In addition, the separation gases (N₂) are supplied to the separation areas D through the separation nozzles 41, 42.

Next, an operation of supplying various gases while rotating the rotational cylinder 2 is described in detail. With reference to FIG. 5, the gas diffusion paths 22-24 rotate in correspondence with the rotation of the rotational cylinder 2. Because the parts of the slits 221, 231, 241, facing the gas supply ports 222, 232, 242 remain constantly open, gases are continuously supplied to the gas diffusion paths 22-24.

The gases supplied to the gas diffusion paths 22-24 are delivered from the reaction gas nozzles 31, 32, the separation gas nozzles 41, 42, to corresponding process areas P1, P2, and the separation areas D via the gas supply pipes 311, 321, 411, and 421. Because the gas supply pipes 311, 321, 411, and 421 are fixed to the rotational cylinder 2, corresponding gases are supplied from the gas supply pipes 311, 321, 411, and 421 to the inside of the vacuum chamber 1 while the gas supply pipes 311, 321, 411, and 421 are rotated in correspondence with the rotation of the rotational cylinder 2. Likewise, because the reaction gas nozzles 31, 32, the separation gas nozzles 41, 42 are fixed to the rotational cylinder 2 via the core part 25, corresponding gases are supplied from the reaction gas nozzles 31, 32, and the separation gas nozzles 41, 42 to the inside of the vacuum chamber 1 while the separation gas nozzles 41, 42 are rotated in correspondence with the rotation of the rotational cylinder 2.

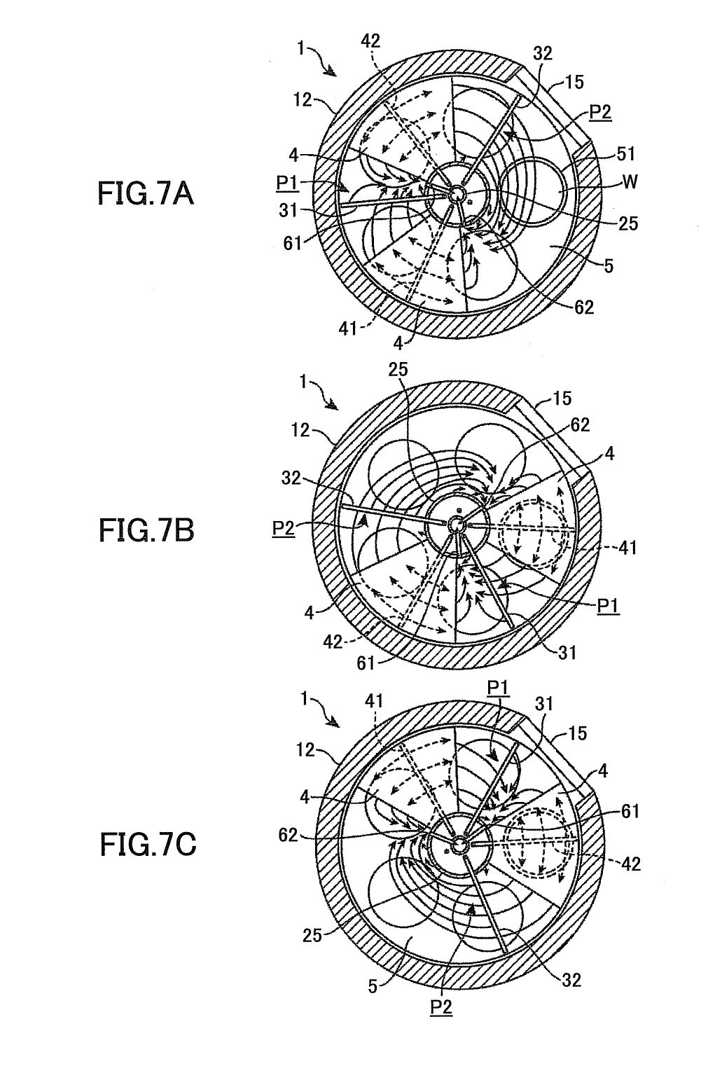

By rotating the gas nozzles 31, 32, 41, 42 inside the vacuum chamber 1, the wafer W alternately passes through the first process area P1 to which BTBAS gas is supplied from the first reaction gas nozzle 31 and the second process area P2 to which O₃ gas is supplied from the second reaction gas nozzle 32 as illustrated in FIGS. 7A-7C. Accordingly, BTBAS molecules are adsorbed on the surface of the wafer W and then O₃ molecules are adsorbed on the surface of the wafer W, so that the BTBAS molecules are oxidized by the O₃ molecules. Thereby, one or more molecular layers of silicon dioxide are formed on the surface of the wafer W. Thus, a silicon dioxide film having a predetermined thickness is formed on the surfaces of the wafers W.

In this embodiment, the sector part 4 rotates in correspondence with the rotation of the reaction gas nozzles 31, 32 and the separation gas nozzles 41, 42. Thereby, the position of the ceiling surface (second ceiling surface 45) above the first reaction gas nozzles 31, 32 moves in correspondence with the sector part 4. Further, the evacuation ports 61, 62, which are provided at upstream sides of the separation gas nozzles 31, 32 in the rotational direction and immediately before (i.e. downstream of) the engaging area between the sector part 4 and the core part 25, move in correspondence with the rotation of the core part 25. In other words, in the film deposition apparatus 1000 according to this embodiment, the reaction gas nozzles 31, 32, the separation gas nozzles 41, 42, the sector part 4, the process area P1, P2, the separation area D, the first ceiling surface 44, the second ceiling surface 45, and the evacuation ports 61, 62 rotate above the susceptor 5 without changing relative positional relationships.

In this case, separation gas (N₂) gas is also supplied from the purge gas supply pipe 76 while rotating in correspondence with the rotational cylinder 2. Thereby, N₂ gas can be ejected along the surface of the susceptor 5 from the center portion area C (i.e. area between the sidewall of the core part and the center part of the susceptor 5). In this embodiment, because the evacuation ports 61, 62 are positioned at the sidewall of the core part 25, the pressure in the space below the second ceiling surface 45 is lower than the pressure in the thin space below the first ceiling surface 44 and lower than the pressure in the center portion area C.

Under the above-described pressure, FIGS. 7A-7C schematically illustrate the flow of gas supplied from each portion. For example, with reference to FIG. 7A, O₃ gas ejected downward from the second reaction gas nozzle 32 contacts the surface of the susceptor 5 (surface of the wafer W and the surface of the susceptor 5 having no wafer W placed thereon) and flows downstream along the surface of the susceptor 5 in the rotation direction. The O₃ gas flowing downstream is pushed back by the N₂ gas flowing from the downstream side and is evacuated by the evacuation port 62. The gas evacuated from the evacuation port 62 is guided to the evacuation pipe 63 via the evacuation entrance conduit 632. Then, the evacuation pipe 63 discharges the gas to the vacuum pump 66 while rotating in correspondence with the rotation of the rotational cylinder 2.

However, not all of the O₃ gas pushed back by the N₂ gas is evacuated by the evacuation port 62. A portion of the O₃ gas is pushed back toward the separation area D adjacently positioned in the upstream direction and is directed to a space below the sector part 4. However, because the height of the ceiling surface 44 of the sector part 4 and the length of the sector part 4 in the circumferential direction are configured to prevent gas from flowing into the space below the sector part 4 in view of the processing parameters (e.g., flow rate of gas) applied during operation, hardly any O₃ gas flows into the space below the sector part 4. Even if a small amount of O₃ gas flows into the space below the sector part 4, the O₃ gas is prevented from reaching the vicinity of the separation gas nozzle 41 by being pushed back by the N₂ gas ejected from the separation gas nozzle 41 in the downstream direction (i.e. toward the process area P2) and evacuated by the evacuation port 62 together with the N₂ gas ejected from the center portion area C.

The BTBAS gas ejected downward from the first reaction gas nozzle 31 flows both upstream and downstream along the surface of the susceptor 5 in the rotation direction and is either completely prevented from entering the space below the sector part 4 or pushed back toward the process area P1 in a case where some of the BTBAS gas enters the space below the sector part 4. Thereby, the BTBAS gas is evacuated at the evacuation port 61 together with the N₂ gas ejected from the center portion area C. In this case, both the BTBAS gas and the N₂ gas ejected from the evacuation port 61 are guided into the evacuation pipe 63 via the evacuation entrance conduit 631. Then, the evacuation pipe 63 discharges the gas to the vacuum pump 66 while rotating in correspondence with the rotation of the rotational cylinder 2.

In each of the separation areas D, although BTBAS gas or O₃ gas flowing in the atmosphere can be prevented from entering, gas molecules adhered on the wafers W can pass through the separation area (i.e. space below the ceiling surface 44 of the sector part 4, and contribute to film deposition.

Further, although BTBAS gas in the process area P1 (O₃ gas in the process area P2) flows toward the center portion area C, the BTBAS gas is prevented from entering the center portion area C by the separation gas ejected to the peripheral edge of the susceptor 5. Even if some of the BTBAS gas enters the center portion area C, the BTBAS gas is pushed back and prevented from flowing into the process area P2 by passing through the center portion area C.

The susceptor 5 has a circumferential edge part which is bent downward (bent part 501) to form a narrow gap between the bent part 501 and the inner circumferential surface of the vacuum chamber 1 that substantially prevents gas from passing therethrough. Accordingly, the BTBAS gas in the first process area P1 (O₃ gas in the second process area P2) is prevented from flowing into the second process area (first process area P1) via the outer side of the susceptor 5. In this embodiment, even in a case where gas (e.g., BTBAS gas) passes through the narrow gap, the gas will not pass through the lower side of the susceptor 5 and enter the O₃ gas supplying area because the lower side of the susceptor 5 is purged with N2 gas. Therefore, the first process area P1 and the second process area P2 are separated by the two separation areas D, so that BTBAS gas is evacuated from the evacuation port 61 and the O₃ gas is evacuated from the evacuation port 62. As a result, both reaction gases (BTBAS gas and O₃ gas) are prevented from mixing with each other in the atmosphere above the wafer W.

The above-described flow of gas in the vacuum chamber 1 illustrated in FIG. 7A realizes substantially the same effects without changing the flow of gas with respect to rotated components of the vacuum chamber 1 in a case where the reaction gas nozzles 31, 32, the separation gas nozzles 41, 42, and the sector parts 4 illustrated in FIGS. 7B and 7C are rotated above the susceptor 5. Accordingly, after the film deposition operation is completed, each wafer W is transferred outside in order by the transfer arm 10.

Here, an example of process parameters is discussed. A rotational speed of the susceptor 5 is, for example, 1 rpm-500 rpm in the case of the wafer W having a diameter of 300 mm. A process pressure is, for example, 1067 Pa (8 Torr). A heating temperature of the wafer W is, for example, 350° C. A flow rate of BTBAS gas is, for example, 100 sccm, and a flow rate of O₃ gas is, for example, 10000 sccm. A flow rate of N₂ gas from the separation gas nozzles 41 and 42 is, for example, 20000 sccm. A flow rate of N₂ gas from the separation gas supplying pipe 51 is, for example, 5000 sccm. In addition, the number of cycles of supplying reaction gas to a single wafer, namely the number of times the wafer passes through the process areas P1 and P2, is, for example, depending on the film thickness required, 600.

With the above-described embodiment of the present invention, a so-called ALD (or MLD) technique is performed by arranging plural wafers W on the susceptor 5 having a top view shape of a circle, arranging the first reaction gas nozzle 31, the second reaction gas nozzle 32, and separation gas nozzles 41, 42 above the susceptor 5 that extend in radial directions in a circumferential direction from the center of the susceptor 5, and rotating the first and second reaction gas nozzles 31, 32, and the separation gas nozzles 41, 42 for allowing the wafers W to pass the first and second process areas P1 and P2 in order. Thereby, film deposition can be performed with high throughput. Further, reaction gases can be prevented from mixing with each other by providing the separation area D having a low ceiling surface between the first and second process areas P1, P2, ejecting separation gas to the outer edge of the susceptor 5 from the center portion area C partitioned by the center portion of the susceptor 5 and the vacuum chamber 1, and evacuating the separation gas diffusing in both sides, the separation gas ejected from the center portion area C, and the reaction gases through the evacuation ports 61, 62 provided at the side wall of the core part 25. As a result, in addition to being able to satisfactorily perform the deposition process, reaction products can be completely eliminated or reduced to an extremely small amount so that particles can be prevented from being formed on the susceptor 5. It is to be noted that a single wafer W may be placed on the susceptor 5 according to an embodiment of the present invention.

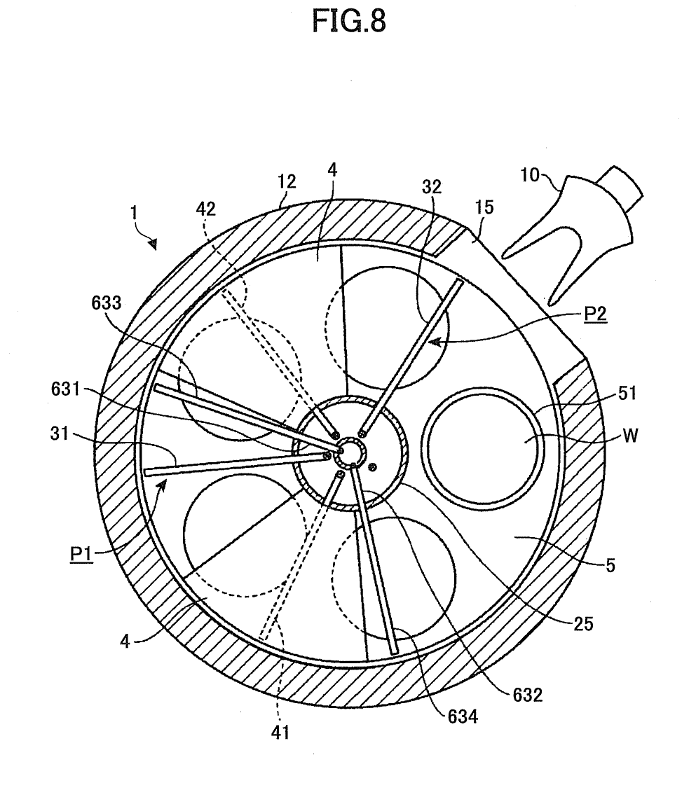

The evacuation of process gas and the separation gas from the first and second process areas P1 and P2 is not limited to the evacuation by the evacuation ports 61, 62 provided at the sidewall of the core part 25 as illustrated in FIGS. 2 and 3. For example, as illustrated in FIG. 8, evacuation nozzles 633, 634 may be provided extending in a radial direction of the susceptor 5 from the sidewall of the core part 25, so that the reaction gas from the first and second process areas P1, P2 and the separation gas can be evacuated through evacuation ports of the evacuation nozzles 633, 634 (described in detail in the second embodiment below).

Further, the above embodiment is described having the first and second reaction gas nozzles 31, 32 and the separation gas nozzles 41, 42 provided above the susceptor 5 and rotated, so that the reaction gases are supplied onto the surface of the wafers W placed on the susceptor 5 in a stationary state. However, the present invention is not limited to this embodiment where the reaction gases are supplied toward the surface of the susceptor 5 in a stationary state. For example, the susceptor 5 may be rotated around a vertical axis in a direction opposite of the rotation direction of the first and second reaction gas nozzles 31, 32, and the separation gas nozzles 41, 42 while being supplied with the reaction gases. In a case where the rotational speed of the first and second reaction gas nozzles 31, 32, and the separation gas nozzles 41, 42 is constant, the relative speed of the first and second reaction gas nozzles 31, 32, and the separation gas nozzles 41, 42 passing above the wafers W increases by rotating the susceptor 5 in the opposite direction as the rotation of the first and second reaction gas nozzles 31, 32, and the separation gas nozzles 41, 42. Thereby, the deposition process can be performed in a shorter time. For example, the driving part 71, which is used for moving the concave part 51 of the susceptor 5 to the position in alignment with the transfer opening 15 when transferring the wafers W in and out of the transfer opening 15, may also serve as a unit (second rotation mechanism) for rotating the susceptor 5.

### Second Embodiment

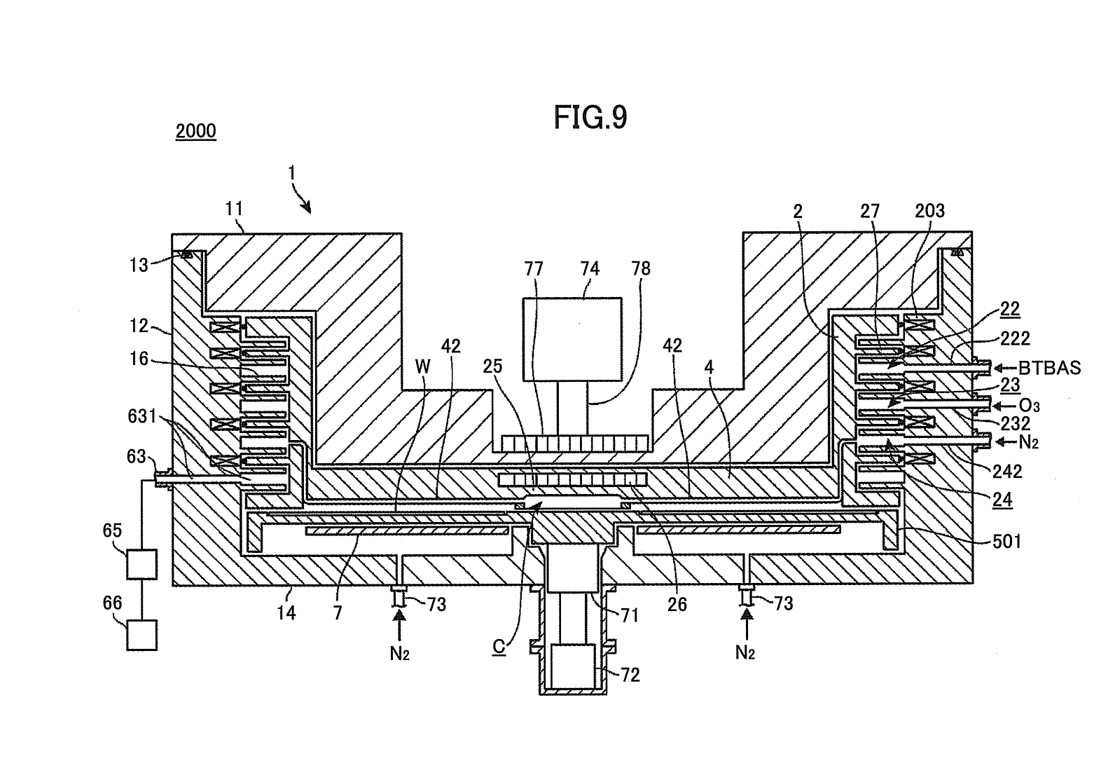

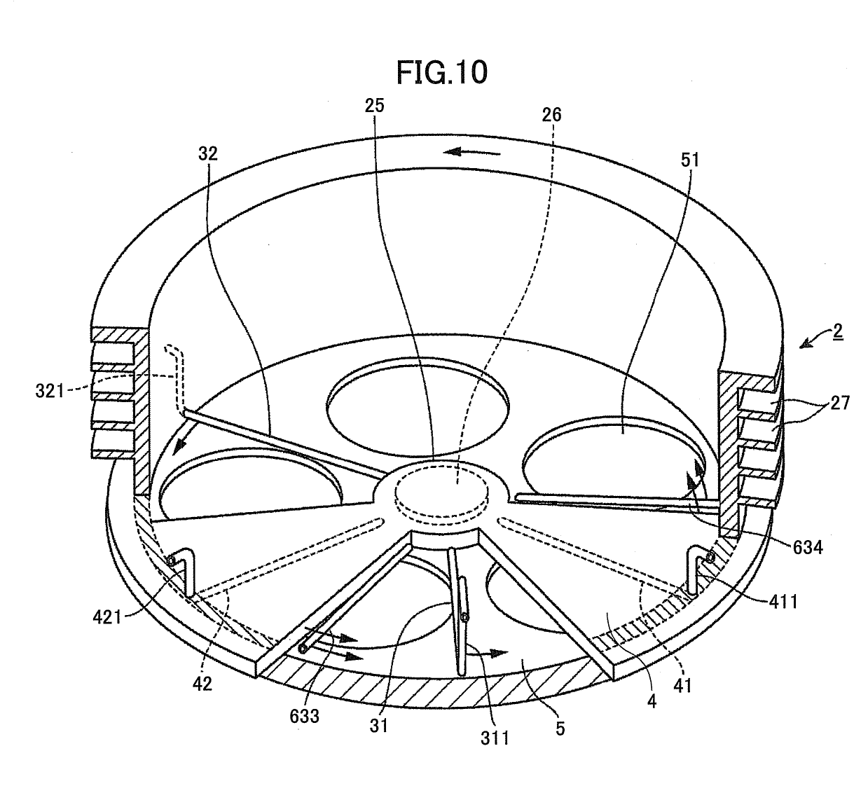

Next, a film deposition apparatus 2000 according to a second embodiment of the present invention is described with reference to FIGS. 9 and 10. The second embodiment is different from the above-described embodiment in that various gases are supplied from the peripheral edges of the susceptor 5 to corresponding first reaction gas nozzle 31, second reaction gas nozzle 32 and the separation nozzles 41, 42 rather than supplying the gases from the center area of the susceptor 5. In the following embodiment, like components are denoted with like reference numerals as of the above-described embodiment and are not further explained.

As illustrated in FIGS. 9 and 10, the film deposition apparatus 2000 is different from the above-described deposition apparatus 1000 in that the rotational cylinder 2 is formed having an inner diameter matching the outer edge part of the susceptor 5, and the sidewall of the vacuum chamber (chamber body 12) of the rotational cylinder 2 is formed to serve as a sleeve covering the rotational cylinder 2.

As illustrated in FIG. 10, protruding edge parts 27 are formed throughout the entire periphery of the rotational cylinder at the outer circumferential surface of the rotational cylinder 2. The protruding edge parts 27 are formed as steps in the vertical direction of the rotational cylinder 2. On the other hand, at the inner circumferential surface of the chamber body 12, protruding edge parts 16 are formed throughout the entire inner circumferential surface of the sidewall of the chamber body 12. For example, as illustrated in FIG. 9, by engaging the protruding edge parts 27 arranged one on top of the other with respect to corresponding protruding edge parts 16 arranged one on top of the other, plural steps of annular flow paths surrounded by the outer circumferential surface of the rotational cylinder 2, the inner circumferential surface of the chamber body 12, and two protruding edge parts 16 are formed extending throughout the entire outer circumferential surface of the rotational cylinder 2. In this embodiment, the annular flow paths form the separation gas diffusion path 22, the first reaction gas diffusion path 23, the second reaction gas diffusion path 24, and the evacuation pipe 63. Magnetic seals are provided above and below each of the gas diffusion paths 22, 23, 24, and the evacuation pipe 63 so that various gases and evacuation gases can be strictly sealed in the gas diffusion paths 22, 23, 24 and the evacuation pipe 63.

As illustrated in FIG. 9, gas supply ports 222, 232, and 242, which have openings facing the gas diffusion ports 22-23, are provided at the sidewall of the chamber body 12. Further, the evacuation pipe 63, which has an opening facing the evacuation entrance conduit 631, is also provided at the sidewall of the chamber body 12. Further, as illustrated in FIG. 10, the first reaction gas pipe 311, the second reaction gas pipe 321, and the separation gas pipes 411, 421 are connected to corresponding gas diffusion paths 22-24. The gas diffusion paths 22-24 extend downward inside the rotational cylinder 2 and connect to corresponding gas nozzles 31, 32, 41, 42 at a lower edge part of the rotational cylinder 2.

The gas nozzles 31, 32, 41, 42 extend in radial directions from the lower edge part of the rotational cylinder 2 (i.e. outer edge part of the susceptor 5) to the center part of the susceptor 5. Further, sector parts 4 are fixed to the lower edge part of the rotational cylinder 2 in a manner allowing the separation gas nozzles 41, 42 to be installed therein. Further, the core part 25 having a flat circle shape is provided at a center portion of the susceptor 5 (i.e. a tip portion of the sector part 4 when viewed from the rotational cylinder 2). The core part 25 has a space provided at its lower surface side. For example, the tips of the separation gas nozzles 41, 42 are connected to the sidewall of the core part 25 for allowing purge gas (separation gas) to be supplied into the space of the core part 25.

The evacuation nozzles 633, 634 are connected to the evacuation entrance conduits 631. The evacuation nozzles 633, 634 also extend in radial directions from the lower edge part of the rotational cylinder 2 (i.e. outer edge part of the susceptor 5) to the center part of the susceptor 5. The evacuation nozzles 633, 634 are arranged immediately in front of the sector parts 4 located upstream of the evacuation nozzles 633, 634 in the rotation direction.

Accordingly, the film deposition apparatus 2000 of the second embodiment can have the gas nozzles 31, 32, 41, 42, the sector parts 4, and the evacuation nozzles 633, 634 arranged above the susceptor 5 in a circumferential direction inside the vacuum chamber 1 in a manner substantially the same as the first embodiment (see FIG. 8).

In this second embodiment, the rotational cylinder 2 is rotated by using, for example, a magnetic drive transmitting mechanism. For example, the ceiling plate 11 of the vacuum chamber 1 includes a center portion having a recess matching the shape of the rotational cylinder 2. A first magnet 77 is provided to the center portion of the ceiling plate 11. Further, a second magnet 26 is, for example, embedded in the upper surface of the core part 25. Accordingly, the first magnet 77 is for rotating the second magnet 26. That is, the first magnet 77, which is connected to the driving part 74 via a rotational shaft 78, is rotated to cause rotation of the second magnet 26. Thereby, the rotational cylinder 2 and the gas nozzles 31, 32, 41, 42, and the sector parts 4 inside the rotational cylinder 2 can be rotated.

With the film deposition apparatus 2000 according to the second embodiment, a flow of gas can be generated inside the vacuum chamber in substantially the same manner as the first embodiment described with FIGS. 7A-7C. It is, however, to be noted that the flow of gas is different in that the evacuation of gas is performed by the evacuation nozzles 633, 634 as illustrated in FIG. 8. As a result, in addition to performing a deposition process with high throughput, the formation of particles can be restrained by preventing reaction gases from mixing with each other.

Further, the same as the first embodiment, reaction gases may be supplied onto the surface of the wafers W in order while rotating the susceptor 5 in a direction opposite to the rotation of the gas nozzles 31, 32, 41, 42 by using the driving part 72.

The reaction gases that may be used in the film deposition apparatus 1000 (2000) of the embodiment of the present invention are dichlorosilane (DCS), hexachlorodisilane (HOD), Trimethyl Aluminum (TMA), tris(dimethyl amino) silane (3DMAS), tetrakis-ethyl-methyl-amino-hafnium (TEMHf), bis(tetra methyl heptandionate) strontium (Sr(THD)₂), (methyl-pentadionate)(bis-tetra-methyl-heptandionate) titanium (Ti(MPD)(THD)), monoamino-silane, or the like.

A larger centrifugal force is applied to the gases in the chamber 1 at a position closer to the outer circumference of the susceptor 5, so that the BTBAS gas, for example, flows toward the separation area D at a higher speed in the position closer to the outer circumference of the susceptor 5. Therefore, the BTBAS gas is more likely to enter the thin space between the ceiling surface 44 and the susceptor 5 in the position closer to the circumference of the susceptor 5. Because of this situation, when the sector part 4 has a greater width (a longer arc) toward the circumference, the BTBAS gas cannot flow farther into the thin space to be mixed with the O₃ gas. On this point, it is preferable for the sector part 4 to have a sector-shaped top view, as explained in the above embodiment.

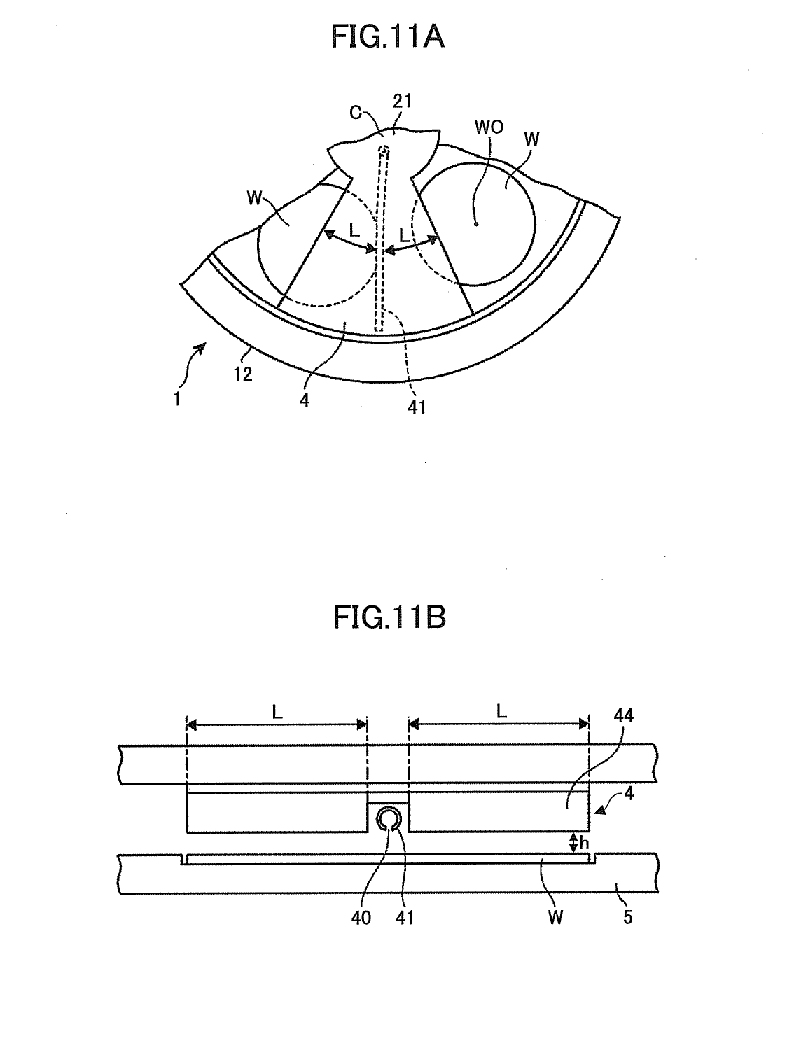

With reference to FIGS. 11A and 11B, in a case where the wafer W has a diameter of 300 mm, the first ceiling surface 44 that creates the thin space in both sides of the separation gas nozzle 41 (42) may preferably have a length L substantially equal to or greater than 50 mm along an arc that corresponds to a route through which a wafer center WO passes. When the length L is short, the height h of the thin space between the ceiling surface 44 and the rotation table 2 (wafer W) has to be accordingly small in order to effectively prevent the reaction gases from flowing into the thin space below the sector part 4 from both sides of the sector part 4. However, when the length L becomes too small and thus the height h of the thin space between the ceiling surface 44 and the susceptor 5 has to be extremely small, the susceptor 5 (or wafer W) may hit the ceiling surface 44, which may cause wafer breakage and wafer contamination through particle generation. Therefore, measures to dampen the vibration of the sector part 4 are required in order to avoid the susceptor 5 hitting the ceiling surface 44. On the other hand, when the height h of the thin space is kept relatively greater while the length L is small, the rotational speed of the sector part 4 has to be lower in order to avoid the reaction gases flowing into the thin space between the ceiling surface 44 and the susceptor 5, which is rather disadvantageous in terms of production throughput. From these considerations, the length L of the ceiling surface 44 along the arc corresponding to the route of the wafer center WO is preferably equal to or greater than approximately 50 mm. It is, however, to be noted that the advantages of the present invention can be attained even where the length L is less than 50 mm. That is, the length L preferably ranges from approximately one-tenth of the diameter of the wafer W through approximately the diameter of the wafer W. More preferably, the length L is approximately one-sixth or more of the diameter of the wafer W.

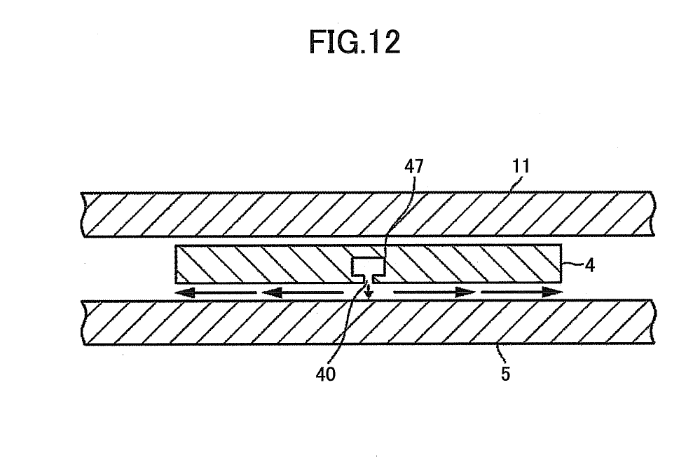

In the above-described embodiments, lower ceiling surfaces 44 are to be located on both sides of a separation gas supplying part (e.g., separation gas nozzle 41 (42)) in the rotation direction of the separation gas supplying part. However, as shown in FIG. 12, according to another embodiment of the present invention, a flow path 47 extending along the radial direction of the susceptor 5 may be made inside the sector part 4, instead of the separation gas nozzle 41 (42). In this embodiment, plural ejection holes 40 may be formed along the longitudinal direction of the flow path 47.

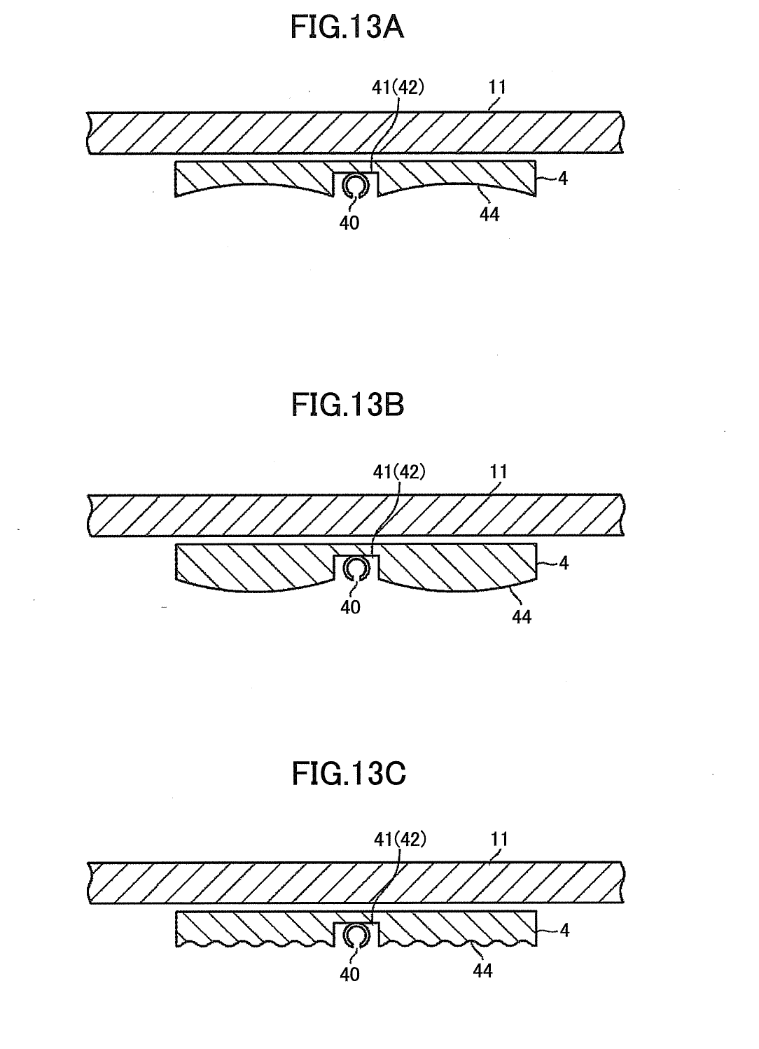

The ceiling surface 44 of the separation area D is not always necessarily flat. For example, the ceiling surface 44 may be concavely curved as shown in FIG. 13A, convexly curved as shown in FIG. 13B, or corrugated as shown in FIG. 13C.

Further, the gas ejection holes 40 of the separation gas nozzles 41, (42) may be arranged as described below.

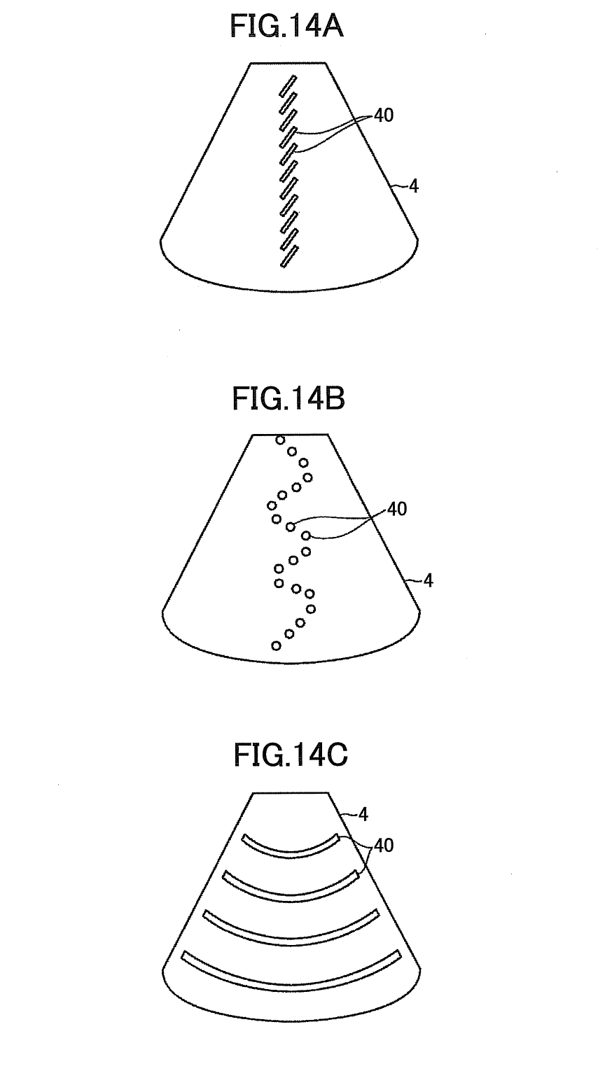

A. In an example shown in FIG. 14A, the gas ejection holes 40 each have a shape of a slanted slit relative to a diameter of the susceptor 5. These slanted slits (gas ejection holes 40) are arranged to be partially overlapped with an adjacent slit along the radial direction of the susceptor 5.
B. In an example shown in FIG. 14B, the gas ejection holes 40 are circular. These circular holes (gas ejection holes 40) are arranged along a serpentine line that extends in the radial direction as a whole.
C. In an example shown in FIG. 14C, each of the gas ejection holes 40 has the shape of an arc-shaped slit. These arc-shaped slits (gas ejection holes 40) are arranged at predetermined intervals in the radial direction.

Further, the separation area 4a having an opposing surface part (hereinafter simply referred to as “opposing surface part 4a”) may have a top view shape as described below.

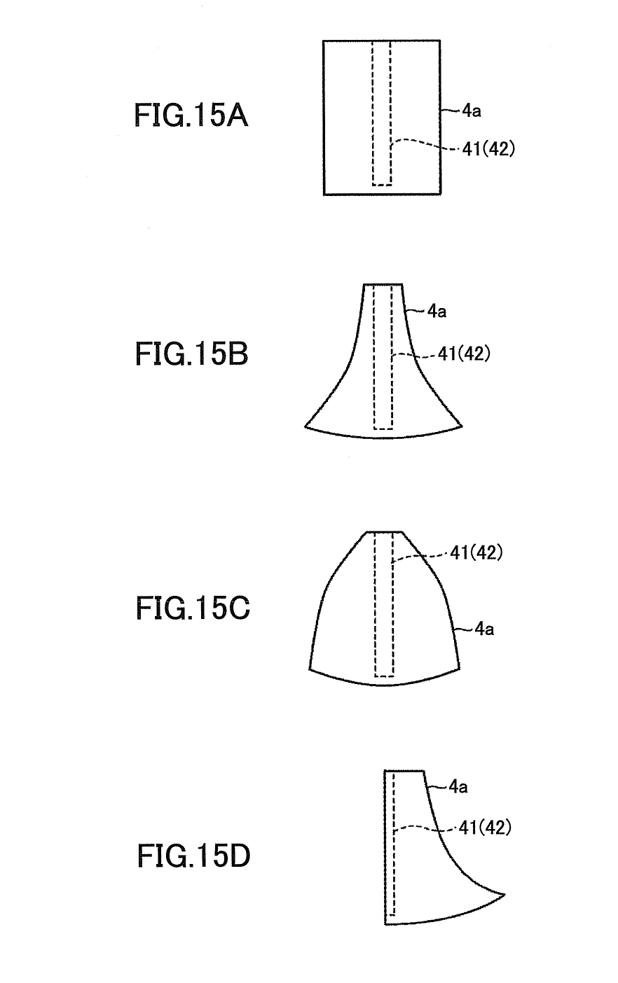

A. In an example shown in FIG. 15A, the opposing surface part 4a has an angular shape (e.g., rectangle).
B. In an example shown in FIG. 15B, the opposing surface part 4a has a shape similar to an end of a trumpet becoming wider as it extends toward the peripheral edge of the vacuum chamber 1.
C. In an example shown in FIG. 15C, the opposing surface part 4a has a shape of a trapezoid having its side edges expanding outward and its long side arranged along the peripheral edge of the vacuum chamber 1.
D. In an example shown in FIG. 15D, the opposing surface part 4a has a sector shape having its downstream side in the rotation direction (right side in FIG. 15D) becoming wider as it extends toward the peripheral edge of the vacuum chamber 1.

The heater part which heats the wafers W may be configured to have a lamp heating element instead of the resistance heating element (e.g., carbon wire heater). In addition, the heater part may be located above the susceptor 5, or above and below the susceptor 5.

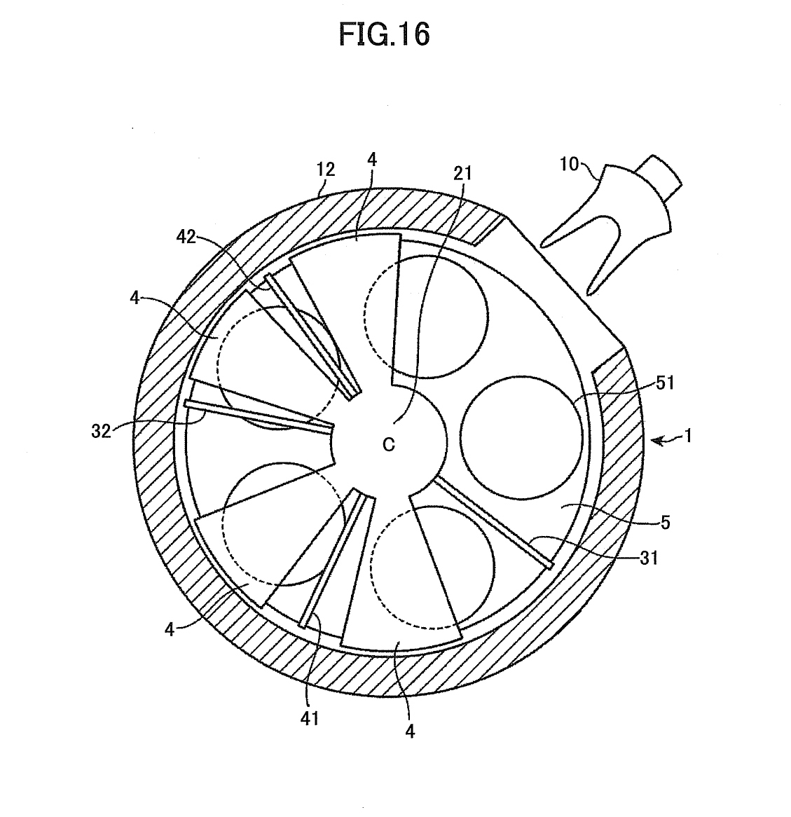

The process areas P1 and P2 and the separation area D may be arranged in other embodiments as described below. In the separation area D, the sector part 4 may be divided into two parts in the circumferential direction and the separation gas nozzle 41 (42) may be provided between the two parts. FIG. 16 shows an example of such a structure. In this case, a distance between the sector part 4 and the separation gas nozzle 41 (42) or a size of the sector part 4 is determined, considering the ejected flow amount of the separation gas or the reaction gas, so that the separation area D can achieve effective separation action.

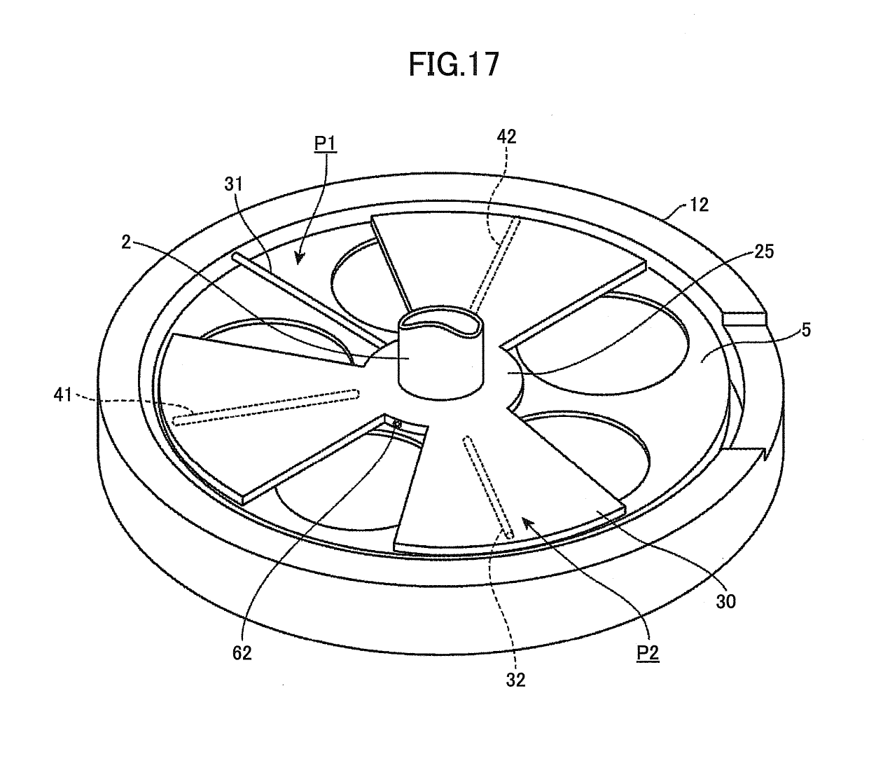

In the above embodiment, the first process area P1 and the second process area P2 correspond to the areas having the ceiling surface 45 higher than the ceiling surface 44 of the separation area D. However, at least one of the first process area P1 and the second process area P2 may have another ceiling surface that opposes the susceptor 5 on both sides of the reaction gas supplying part (e.g., reaction gas supplying nozzle 31 (32)) and is lower than the ceiling surface 45 in order to prevent gas from flowing into a gap between the ceiling surface concerned and the susceptor 5. This ceiling surface, which is lower than the ceiling surface 45, may be as low as the ceiling surface 44 of the separation area D. FIG. 17 shows an example of such a configuration. As illustrated in FIG. 17, the second reaction gas nozzle 32 is arranged below the sector part 30 in the second process area P2 (in this example, area where O₃ is adsorbed on the wafer W). In this example, the second process area P2 substantially has the same configuration as the separation area D other than providing the second reaction gas nozzle 32 instead of the separation gas nozzle 41 (42).

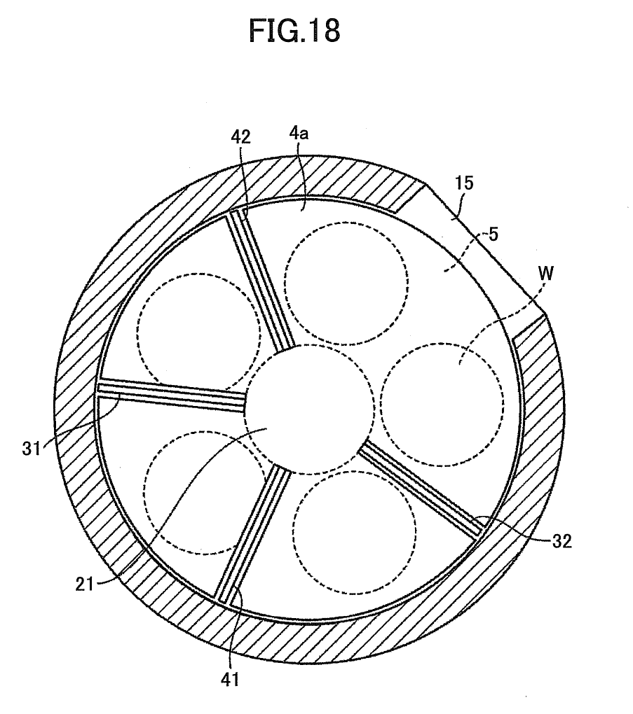

In the above-described embodiments of the present invention, the low ceiling surfaces 44 are provided on both sides of the reaction gas nozzle 41 (42) for making the thin space. However, as illustrated in FIG. 18, according to another embodiment, a low ceiling surface provided on both sides of the reaction gas nozzles 31 (32) is formed having a continuous configuration. That is, other than the areas where the separation gas nozzle 41 (42) and the reaction gas nozzle 31 (32) are provided, the opposing surface part 4a is formed throughout the area facing the susceptor 5. Even with this configuration, the above-described advantages of the present invention can be attained. From another view point, this configuration has the low ceiling surface 44 expanded to the reaction gas nozzle 31 (32). With this configuration, separation gas diffuses to both sides of the separation gas nozzle 41 (42) and reaction gases diffuse to both sides of the reaction gas nozzles 31 (32), so that the separation gas and the reaction gases are merged at the area below the opposing surface part 4a and evacuated from the evacuation ports 61 (62) positioned between the reaction gas nozzle 31 (32) and the separation gas nozzle 41 (42).

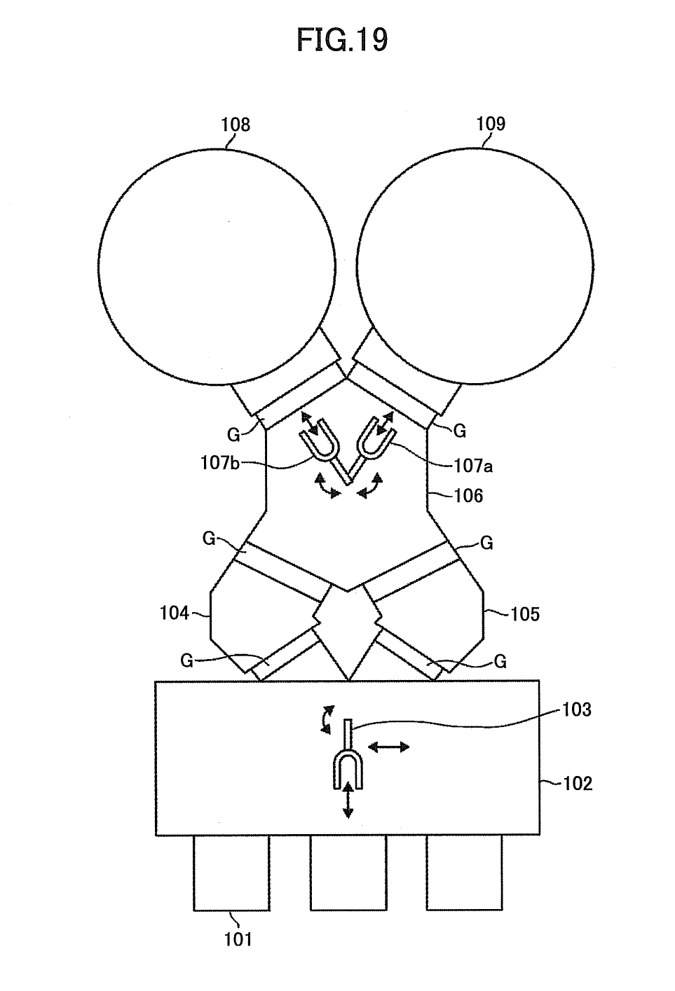

The film deposition apparatus (exemplarily indicated with reference numerals 108, 109 in FIG. 19) according to embodiments of the present invention may be integrated into a substrate process apparatus, an example of which is schematically illustrated in FIG. 19. The substrate process apparatus includes a hermetic type wafer transfer cassette 101 called a Front Opening Unified Pod (FOUP) where, for example, there are 25 pieces of the wafers; an atmospheric transfer chamber 102 in which a transfer arm 103 is provided; load lock chambers (preparatory vacuum chambers) 104 and 105 whose atmospheres are changeable between vacuum and atmospheric pressure; a vacuum transfer chamber 106 in which two transfer arms 107a and 107b are provided; and film deposition apparatuses 108 and 109 according to embodiments of the present invention. The wafer transfer cassette 101 is brought onto one of the cassette stages, and connected to a transfer in/out port provided between the cassette stage and the atmospheric transfer chamber 102. Then, a lid of the wafer cassette (FOUP) 101 is opened by an opening/closing mechanism (not shown) and the wafer is taken out from the wafer transfer cassette 101 by the transfer arm 103. Next, the wafer is transferred to the load lock chamber 104 (105). After the load lock chamber 104 (105) is evacuated, the wafer in the load lock chamber 104 (105) is transferred further to one of the film deposition apparatuses 108 and 109 by the transfer arm 107a (107b). In the film deposition apparatus 108 (109), a film is deposited on the wafer in such a manner as described above. Because the substrate process apparatus has two film deposition apparatuses 108, 109 that can house five wafers at a time, the ALD (or MLD) mode deposition can be performed at high throughput.

With the above-described embodiments of the present invention, film deposition can be performed with high throughput, reaction gas can be prevented from entering the separation area, and different reaction gases can be prevented from mixing with each other, so that a satisfactory film deposition process can be performed.

Further, the present invention is not limited to these embodiments, but variations and modifications may be made without departing from the scope of the present invention.

What is claimed is:

1. A film deposition apparatus for depositing a film on a substrate by carrying out a cycle of alternately supplying at least two kinds of reaction gases that react with each other to the substrate to produce a layer of a reaction product in a chamber, the film deposition apparatus comprising:
a rotational member that is rotatable around a vertical axis inside the chamber;
a rotation mechanism configured to rotate the rotational member;
a pedestal provided in the chamber, the pedestal including a plurality of substrate receiving areas formed along a circle having the vertical axis as a center;
a first reaction gas supplying part provided in the rotational member and configured to supply a first reaction gas to the pedestal;
a second reaction gas supplying part provided in the rotational member and configured to supply a second reaction gas to the pedestal, the second reaction gas supplying part being separated from the first reaction gas supplying part along a circumferential direction of the circle;
a separating area provided in the rotational member along the circumferential direction of the circle, the separating area being arranged between a first process area to which the first reaction gas is supplied and a second process area to which the second reaction gas is supplied for separating an atmosphere of the first process area and an atmosphere of the second process area;
an evacuation port configured to evacuate an atmosphere inside the chamber;
a separation gas supplying part provided in the separating area and configured to supply a separation gas; and
an opposing surface part provided in the separating area on both sides of the separation gas supplying part in the circumferential direction of the circle and arranged at a position forming a thin space between the opposing surface part and the pedestal for allowing the separation gas to flow from the separating area to the first and second process areas.

2. The film deposition apparatus as claimed in claim 1, wherein the evacuation port is provided in the rotational member.

3. The film deposition apparatus as claimed in claim 1, wherein the evacuation port is provided on both sides of the separation area in a rotation direction of the rotational member.

4. The film deposition apparatus as claimed in claim 1, further comprising:
a flow path provided in the rotational member; and
a gas supplying mechanism configured to supply at least one of the reaction gas and the separation gas to the flow path;
wherein the gas supplying mechanism includes
an annular flow path having an outer side that is open across the entire circumference of the rotational member, and
a gas supply port provided at an outer circumference of the rotational member in a manner facing the outer side of the annular flow path.

5. The film deposition apparatus as claimed in claim 1, further comprising:
another rotational mechanism configured to rotate the pedestal in a direction opposite to a rotation direction of the rotational member.

6. The film deposition apparatus as claimed in claim 1, further comprising:
a narrow space provided between an outer edge part of the separation area and an inner circumferential surface of the chamber.

7. The film deposition apparatus as claimed in claim 1, wherein the separation area has a pressure that is higher than a pressure in the first process area and higher than a pressure in the second process area.

8. The film deposition apparatus as claimed in claim 1, wherein the separation gas supplying part includes a plurality of gas ejection holes;
wherein the plural gas ejection holes are arranged from one end to the other end either from a center part of the pedestal or a peripheral edge part of the pedestal.

9. The film deposition apparatus as claimed in claim 1, further comprising:
a heating part configured to heat the pedestal.

10. The film deposition apparatus as claimed in claim 1, wherein the opposing surface part has a size equal to or greater than 50 mm along an arc that corresponds to a route through which a wafer center passes in the circumferential direction of the circle.

11. The film deposition apparatus as claimed in claim 1, wherein the opposing surface part includes a downstream part located downstream with respect to the separation gas supplying part in the circumferential direction of the circle,
wherein the downstream part becomes wider in the circumferential direction the closer to an outer edge of the opposing surface part

12. The film deposition apparatus as claimed in claim 11, wherein the downstream part has a sector shape.
